(19) United States
(12) Patent Application Publication
(10) Pub. No.: US 2025/0022994 A1
(43) Pub. Date: Jan. 16, 2025

(54) DISPLAY DEVICE

(71) Applicant: Samsung Display Co., LTD., Yongin-si (KR)

(72) Inventors: Myeong Su SO, Yongin-si (KR); Sang Wook HAN, Yongin-si (KR); Na Mi HONG, Yongin-si (KR)

(73) Assignee: Samsung Display Co., LTD., Yongin-si (KR)

(21) Appl. No.: 18/641,969

(22) Filed: Apr. 22, 2024

(30) Foreign Application Priority Data
Jul. 11, 2023 (KR) 10-2023-0089818

(51) Int. Cl. H01L 33/60; H01L 25/16; H01L 33/62

(52) U.S. Cl. CPC H01L 33/60; H01L 25/167; H01L 33/62

(57) ABSTRACT

A display device includes an electrode disposed on a substrate, an organic pattern layer disposed on the substrate and spaced apart from the electrode, a light emitting element disposed on the organic pattern layer, the light emitting element including a contact electrode contacting the organic pattern layer, a first semiconductor layer, an active layer, and a second semiconductor layer sequentially disposed on the contact electrode and a connection electrode electrically connecting the electrode to the contact electrode, and the connection electrode is disposed along an upper surface of the electrode, a side surface of the organic pattern layer, and a side surface of the contact electrode.

### CROSS-REFERENCE TO RELATED APPLICATION(S)

This application claims priority to and benefits of Korean Patent Application No. 10-2023-0089818 under 35 U.S.C. § 119 filed on Jul. 11, 2023, in the Korean Intellectual Property Office, the entire contents of which are incorporated herein by reference.

### BACKGROUND

### 1. Technical Field

The disclosure relates to a display device.

### 2. Description of the Related Art

Display devices are becoming increasingly important with the development of multimedia. In response to this, various types of display devices, such as organic light emitting displays (OLED) and liquid crystal displays (LCD), are being used.

A device for displaying an image of a display device may include a display panel such as an organic light emitting display panel or a liquid crystal display panel. Among them, the light emitting display panel may include a light emitting element. For example, light emitting diodes (LED) include organic light emitting diodes (OLED) that utilize organic materials as light emitting materials, inorganic light emitting diodes that utilize inorganic materials as light emitting materials, and the like.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects and features of embodiments provide a display device capable of low-temperature and low-pressure bonding of light emitting elements.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an embodiment, a display device may include an electrode disposed on a substrate; an organic pattern layer disposed on the substrate and spaced apart from the first electrode, a light emitting element disposed on the organic pattern layer, the light emitting element including a contact electrode contacting the organic pattern layer, a first semiconductor layer, an active layer, and a second semiconductor layer sequentially disposed on the contact electrode and a connection electrode electrically connecting the electrode to the contact electrode, wherein the connection electrode is disposed along an upper surface of the first electrode, a side surface of the organic pattern layer, and a side surface of the contact electrode.

The display device may include a light emitting area and a non-emitting area, wherein the organic pattern layer overlaps the emitting area and does not overlap the non-emitting area.

The organic pattern layer may have a substantially island pattern shape.

The contact electrode may comprise a first portion disposed on the first semiconductor layer and contacting the first semiconductor layer, a second portion extending from the first portion and surrounding at least a portion of a side surface of the light emitting element.

The connection electrode may surround at least a portion of a side surface of the light emitting element on the contact electrode.

The display device may further comprise a first via layer disposed on the connection electrode and the substrate on which the connection electrode is not disposed, a second via layer disposed on the first via layer and a common electrode disposed on the light emitting element.

An upper surface of the first via layer may have a same height as an end of a connection electrode disposed along the second portion of the contact electrode.

The first electrode may overlap the non-emitting area and does not overlap the emitting area.

The light emitting element may further comprise a first insulating layer surrounding side surfaces of the first semiconductor layer, the active layer, the second semiconductor layer and an upper surface of the first semiconductor layer, the first insulating layer having a first opening on the first semiconductor layer, wherein the contact electrode directly contacts the first semiconductor layer through the first opening of the first insulating layer.

The light emitting element may further comprise a second insulating layer surrounding side surfaces of the first semiconductor layer, the active layer, and the second semiconductor layer and an upper surface of the first semiconductor layer and a reflective layer surrounding side surfaces of the light emitting element on the second insulating layer, wherein the first insulating layer is disposed on the reflective layer and directly contacts the second portion of the contact electrode.

The reflective layer may be surrounded by the first insulating layer and the second insulating layer and does not contact the contact electrode.

The display device may further comprise a partition wall part disposed on the common electrode and overlapping the non-emitting area, a wavelength conversion layer disposed between the partition wall part and a color filter layer disposed on the wavelength conversion layer.

According to an embodiment, a display device may include an electrode disposed on a substrate; an organic pattern layer disposed on the electrode; a light emitting element disposed on the organic pattern layer, the light emitting element including a contact electrode contacting the organic pattern layer, a first semiconductor layer, an active layer, and a second semiconductor layer sequentially disposed on the contact electrode and a connection electrode electrically connecting the electrode to the contact electrode, wherein a portion of an upper surface of the electrode does not overlap the organic pattern layer, the connection electrode is disposed on a portion of an upper surface of the first electrode that does not overlap the organic pattern layer, a side surface of the organic pattern layer, and a side surface of the contact electrode.

The contact electrode may comprise a first portion disposed on the first semiconductor layer and contacting the first semiconductor layer, a second portion extending from the first portion and surrounding at least a portion of a side surface of the light emitting element.

The connection electrode may surround at least a portion of a side surface of the light emitting element on the contact electrode.

The display device may further comprise a first via layer disposed on the connection electrode and the substrate on which the connection electrode is not disposed, a second via layer disposed on the first via layer and a common electrode disposed on the light emitting element.

An upper surface of the first via layer may have a same height as an end of a connection electrode disposed along the second portion of the contact electrode.

The light emitting element may further comprise a first insulating layer surrounding side surfaces of the first semiconductor layer, the active layer, the second semiconductor layer and an upper surface of the first semiconductor layer, the first insulating layer having a first opening on the first semiconductor layer, wherein the contact electrode directly contacts the first semiconductor layer through the first opening of the first insulating layer.

The light emitting element may further comprise a second insulating layer surrounding side surfaces of the first semiconductor layer, the active layer, and the second semiconductor layer and an upper surface of the first semiconductor layer, and a reflective layer surrounding side surfaces of the light emitting element on the second insulating layer, wherein the first insulating layer is disposed on the reflective layer and directly contacts the second portion of the contact electrode.

The display device may include an emitting area and a non-emitting area. The display device may further comprise a partition wall part disposed on the common electrode and overlapping the non-emitting area, a wavelength conversion layer disposed between the partition wall part and a color filter layer disposed on the wavelength conversion layer.

Since a display device according to one embodiment performs bonding using an organic pattern layer, problems caused by eutectic bonding may be solved by omitting eutectic bonding.

However, the effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to one embodiment.

FIG. 2 is a schematic plan view of a circuit of a display substrate of a display device according to one embodiment.

FIG. 3 is a schematic diagram of an equivalent circuit of one-pixel of a display device according to one embodiment.

FIG. 4 is a schematic diagram of an equivalent circuit of one-pixel of a display device according to an embodiment.

FIG. 5 is a schematic diagram of an equivalent circuit of one-pixel of a display device according to an embodiment.

FIG. 6 is a schematic cross-sectional view of a display device according to one embodiment.

FIG. 7 is an enlarged view of area A of FIG. 6.

FIG. 8 is a schematic plan view illustrating light emitting areas of the display device.

FIG. 9 is an enlarged view of area A according to an embodiment.

FIG. 10 is a schematic cross-sectional view of a display device according to an embodiment.

FIG. 11 is an enlarged view of area B of FIG. 10.

FIG. 12 is a schematic plan view illustrating light emitting areas of the display device.

FIGS. 13 to 33 are schematic diagrams for explaining a method of manufacturing a display device according to one embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The expression “not overlap” may include meaning such as “apart from” or “set aside from” or “offset from” and any other suitable equivalents as would be appreciated and understood by those of ordinary skill in the art.

The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween.

It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

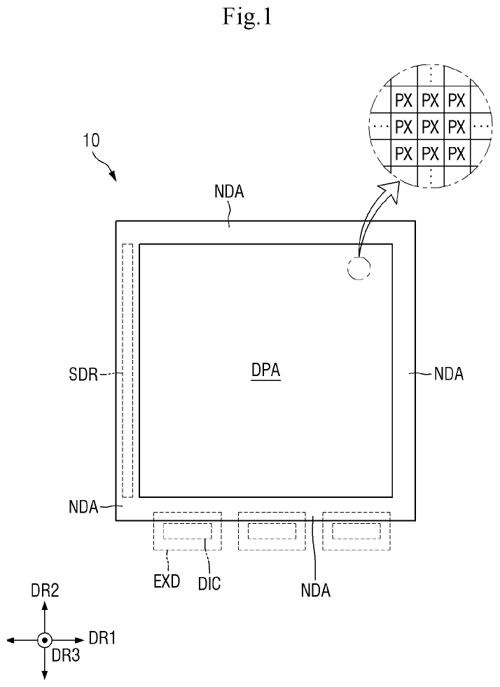

FIG. 1 is a schematic plan view of a display device according to one embodiment.

Referring to FIG. 1, a display device 10 according to one embodiment may be applied to various consumer electronics, or internet of things devices, such as smartphones, cell phones, tablet PC, personal digital assistants (PDA), portable multimedia players (PMP), televisions, gaming devices, watch-type electronic devices, head-mounted displays, monitors of personal computers, laptop computers, car navigation, car instrument panels, digital cameras, camcorders, exterior billboards, billboards, medical devices, inspection devices, refrigerators, and washing machines, and the like within the spirit and the scope of the disclosure. A television is described herein as an example of the display device, and the television may have a high or ultra-high resolution, such as HD, UHD, 4K, 8K, etc.

The display device 10 according to some embodiments may be variously categorized based on how it is displayed. For example, the classification of the display device may include an organic light emitting display device (OLED), an inorganic light emitting display device (inorganic EL), a quantum dot light emitting display device (QED), a micro-LED display device (micro-LED), a nano-LED display device (nano-LED), a plasma display device (PDP), a field emission display device (FED), a cathode ray tube display device (CRT), a liquid crystal display device (LCD), an electrophoretic display device (EPD), and the like within the spirit and the scope of the disclosure. In the following, the organic light emitting display device will be described as an example of a display device, and the organic light emitting display device applied in an embodiment will be abbreviated simply as a display device unless otherwise indicated. However, embodiments are not limited to organic light emitting display device, and other display devices listed above may be employed to the extent that they share technical ideas.

Furthermore, in the following drawings, a first direction DR1 refers to a horizontal direction of the display device 10, a second direction DR2 refers to a vertical direction of the display device 10, and a third direction DR3 refers to a thickness direction of the display device 10. “Left”, “right”, “up”, and “down” refer to directions when the display device 10 is viewed from a plane. For example, “right” refers to one side or a side of the first direction DR1, “left” refers to the other side or another side of the first direction DR1, “top” refers to one side or a side of the second direction DR2, and “bottom” refers to the other side or another side of the second direction DR2. Further, “upper” refers to a first side of the third direction DR3 and “lower” refers to a second side of the third direction DR3.

The display device 10 according to one embodiment may have a square shape in plan view, for example, a square shape. Also, if the display device 10 is a television, it may have a rectangular shape with the long sides disposed in the transverse direction. However, it is not limited to this, the long sides may be disposed in the longitudinal direction, and it may be rotatably mounted so that the long sides are variably disposed in the horizontal or vertical direction. The display device 10 may also have a circular or oval shape.

The display device 10 may include a display area DPA and a non-display area NDA. The display area DPA may be an active area where the video is displayed. The display area DPA may have a square shape in plan view similar to the overall shape of the display device 10 but is not limited thereto.

The display area DPA may include pixels PX. The pixels PX may be arranged (or disposed) in a matrix orientation. The shape of each pixel PX may be rectangular or square in plan view, but is not limited thereto, and may also be rhombic in shape with each side inclined toward one side or a side of the display device 10. The pixels PX may include multiple color pixels PX. For example, the pixels may include a first color pixel PX of red, a second color pixel PX of green, and a third color pixel PX of blue but are not limited thereto. Each color pixel PX may be alternately arranged in a stripe-type or a pentile-type (PENTILE™).

The non-display area NDA may be disposed on the periphery of the display area DPA. The non-display area NDA may fully or partially enclose the display area DPA. The display area DPA may be square in shape, and the non-display areas NDA may be arranged to be adjacent to the four sides of the display area DPA. The non-display area NDA may comprise a bezel of the display device 10.

A driving circuit or a driving element for driving the display area DPA may be disposed in the non-display area NDA. In one embodiment, the non-display area NDA disposed adjacent to the first side (lower side in FIG. 1) of the display device 10 may have a pad portion provided on the display substrate of the display device 10, and an external device EXD may be mounted on the pad electrode of the pad portion. Examples of the external device EXD include a connection film, a printed circuit board, a driving chip (DIC), a connector, a wiring connection film, and the like within the spirit and the scope of the disclosure. In the non-display area NDA disposed adjacent to the second side (left side in FIG. 1) of the display device 10, a scan driving unit SDR (or scan driving part or scan driver), or the like formed directly on the display substrate of the display device 10 may be disposed.

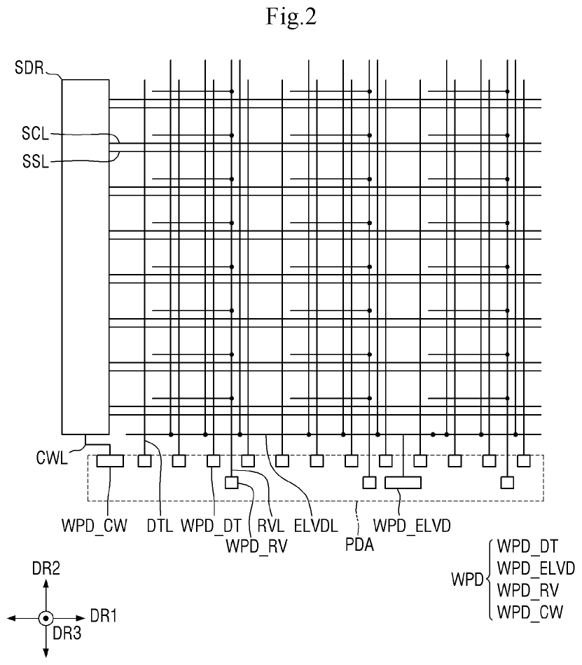

FIG. 2 is a schematic plan view of a circuit of a display substrate of a display device according to one embodiment.

Referring to FIG. 2, lines is disposed on the substrate. The lines may include a scan line SCL, a sensing signal line SSL, a data line DTL, a reference voltage line RVL, a first power supply line ELVDL, and the like within the spirit and the scope of the disclosure.

The scan line SCL and the sensing signal line SSL may be extended in the first direction DR1. The scan line SCL and the sensing signal line SSL may be connected to the scan driving unit SDR (or scan driving part or scan driver). The scan driving unit SDR (or scan driving part or scan driver) may include a driving circuit. The scan driving unit SDR (or scan driving part or scan driver) may be disposed on one side or a side of the non-display area NDA on the display substrate but may also be disposed on both sides of the non-display area NDA. The scan driving unit SDR (or scan driving part or scan driver) may be connected to a signal connection line CWL, and at least one end of the signal connection line CWL may be connected to an external device (“EXD” in FIG. 1) by forming a pad (WPD_CW) on the first non-display area NDA and/or the second non-display area NDA.

The data line DTL and the reference voltage line RVL may be extended in the second direction DR2 intersecting the first direction DR1. The first power supply line ELVDL may include a portion extending in the second direction DR2. The first power supply line ELVDL may further include a portion extending in the first direction DR1. The first power supply line ELVDL may have a mesh structure but is not limited thereto.

Wiring pads WPD may be disposed at at least one end of the data line DTL, the reference voltage line RVL, and the first power supply line ELVDL. Each wiring pad WPD may be disposed on a pad area PDA of the non-display area (NDA). In one embodiment, a wiring pad (WPD_DT, hereinafter referred to as a “data pad”) for a data line DTL, a wiring pad (WPD_RV, hereinafter referred to as a “reference voltage pad”) for the reference voltage line RVL, and a wiring pad (WPD_ELVD, hereinafter referred to as a “first power pad”) for a first power supply line ELVDL may be disposed on the pad area PDA of the non-display area NDA. In another example, the data pad WPD_DT, the reference voltage pad WPD_RV, and the first power supply pad WPD_ELVD may be disposed in different non-display areas NDA. An external device (“EXD” in FIG. 1) may be mounted on the wiring pad WPD as described above. The external device EXD may be mounted on the wiring pad WPD through an anisotropic conductive film, ultrasonic bonding, or the like within the spirit and the scope of the disclosure.

Each pixel PX on the display board may include a pixel driving circuit. The wiring described above may pass through or around each pixel PX and apply a driving signal to each pixel driving circuit. The pixel driving circuit may include a transistor and a capacitor. The number of transistors and capacitors in each pixel driving circuit may be varied. Hereinafter, the pixel driving circuit will be described taking a 3T1C structure including three transistors and one capacitor as an example, but is not limited thereto, and various other modified pixel PX structures such as a 2T1C structure, a 7T1C structure, and a 6T1C structure may be applied.

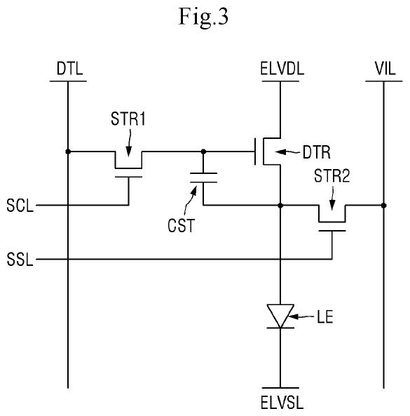

FIG. 3 is a schematic diagram of an equivalent circuit of one-pixel of a display device according to one embodiment.

Referring to FIG. 3, each pixel PX of the display device according to one embodiment may include, in addition to the light emitting element LE, three transistors DTR, STR1 and STR2 and one capacitor CST for storage.

The light emitting element LE emits light in response to a current supplied through a driving transistor DTR. The light emitting element LE may be implemented as an inorganic light emitting diode, an organic light emitting diode, a micro light emitting diode, a nano light emitting diode, or the like within the spirit and the scope of the disclosure.

A first electrode (for example, an anode electrode) of the light emitting element LE may be connected to a source electrode of the driving transistor DTR, and a second electrode (for example, a cathode electrode) may be connected to a second power supply line ELVSL supplied with a low potential voltage (second power supply voltage) lower than a high potential voltage (first power supply voltage) of the first power supply line ELVDL.

The driving transistor DTR adjusts the current flowing to the light emitting element LE from the first power supply line ELVDL supplied with the first power voltage according to the voltage difference between a gate electrode and the source electrode. The gate electrode of the driving transistor DTR may be connected to the first electrode of the first transistor ST1, the source electrode may be connected to the first electrode of the light emitting element LE, and a drain electrode may be connected to the first power supply line ELVDL to which the first power supply voltage is applied.

A first transistor STR1 is turned-on by a scan signal on the scan line SCL to connect the data line DTL to the gate electrode of the driving transistor DTR. The gate electrode of the first transistor STR1 may be connected to the scan line SL, the first electrode may be connected to the gate electrode of the driving transistor DTR, and the second electrode may be connected to the data line DTL.

A second transistor STR2 is turned-on by a sensing signal on the sensing signal line SSL to connect an initialization voltage line VIL to the source electrode of the driving transistor DTR. The gate electrode of the second transistor ST2 may be connected to the sensing signal line SSL, the first electrode may be connected to the initialization voltage line VIL, and the second electrode may be connected to the source electrode of the driving transistor DTR.

In one embodiment, the first electrode of each of the first and second transistors STR1 and STR2 may be the source electrode and the second electrode may be the drain electrode, but is not limited to, and may be vice versa.

The capacitor CST is formed between the gate and source electrodes of the driving transistor DTR. A storage capacitor CST stores the difference voltage between the gate voltage of the driving transistor DTR and the source voltage.

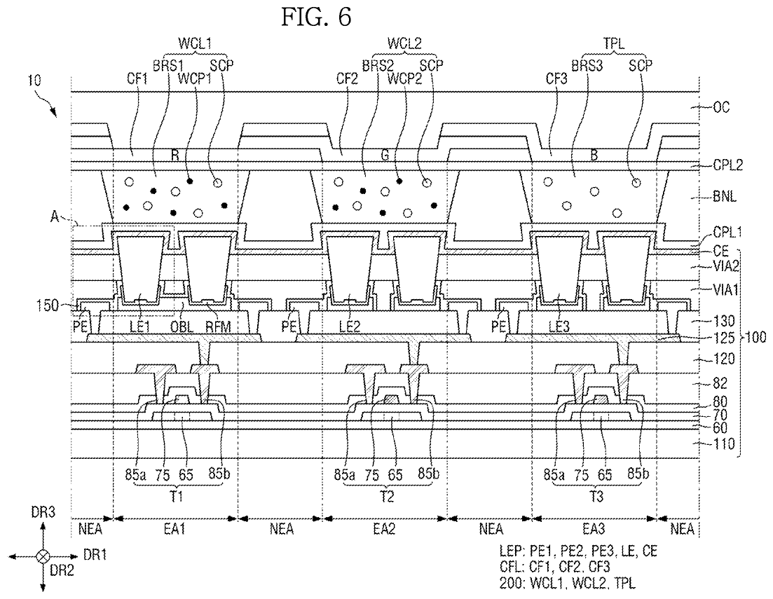

The driving transistor DTR and the first and second transistors STR1 and STR2 may be formed as thin film transistors. Furthermore, while FIG. 6 describes the driving transistor DTR and the first and second switching transistors STR1 and STR2 as being N-type MOSFET (metal oxide semiconductor field effect transistors), it is not limited to thereto. For example, the driving transistor DTR and the first and second switching transistors STR1 and STR2 may be P-type MOSFET, or some may be N-type MOSFET, and others may be P-type MOSFET.

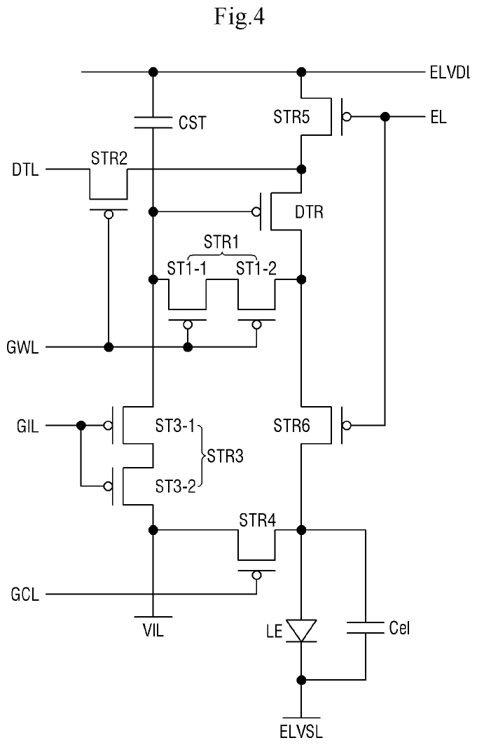

FIG. 4 is a schematic diagram of an equivalent circuit of one-pixel of a display device according to an embodiment.

Referring to FIG. 4, the first electrode of the light emitting element LE may be connected to the first electrode of the fourth transistor STR4 and the second electrode of the sixth transistor STR6, and the second electrode may be connected to the second power supply line ELVSL. A parasitic capacity Cel may be formed between the first electrode and the second electrode of the light emitting element LE.

Each pixel PX may include the driving transistor DTR, switch elements, and the capacitor CST. The switch elements include first to sixth transistors STR1, STR2, STR3, STR4, STR5, and STR6. The first transistor STR1 may include further transistors ST1-1 and ST1-2. The third transistor STR3 may include further transistors ST3-1 and ST3-2.

The driving transistor DTR may include the gate electrode, the first electrode, and the second electrode. The driving transistor DTR controls the drain-to-source current (Ids, hereinafter referred to as the “driving current”) flowing between the first and second electrodes based on the data voltage applied to the gate electrode.

The capacitor CST is formed between the second electrode of the driving transistor DTR and the second power supply line ELVSL. One electrode of the capacitor CST may be connected to the second electrode of the driving transistor DTR, and the other electrode may be connected to the second power supply line ELVSL.

In case that the first electrode of each of the first to sixth transistors STR1, STR2, STR3, STR4, STR5, and STR6 and the driving transistor DTR is the source electrode, the second electrode may be the drain electrode. For example, if the first electrode of each of the first to sixth transistors STR1, STR2, STR3, STR4, STR5, and STR6 and the driving transistor DTR is the drain electrode, the second electrode may be the source electrode.

An active layer of each of the first to sixth transistors STR1, STR2, STR3, STR4, STR5, and STR6 and the driving transistor DTR may be formed from any of poly silicon, amorphous silicon, and oxide semiconductors. In case that the semiconductor layer of each of the first through sixth transistors STR1, STR2, STR3, STR4, STR5, and STR6 and the driving transistor DTR is formed from poly silicon, the process for forming it may be a low temperature poly silicon (LTPS) process.

In FIG. 4, the first to sixth transistors STR1, STR2, STR3, STR4, STR5, and STR6 and the driving transistor DTR are described centering on the P-type MOSFET (Metal Oxide Semiconductor Field Effect Transistor), but are not limited thereto, and may be formed as the N-type MOSFET.

Further, the first power supply voltage of the first power supply line ELVDL, the second power supply voltage of the second power supply line ELVSL, and the third power supply voltage of the third power supply line VIL may be set by considering the characteristics of the driving transistor DTR, the characteristics of the light emitting element LE, and the like within the spirit and the scope of the disclosure.

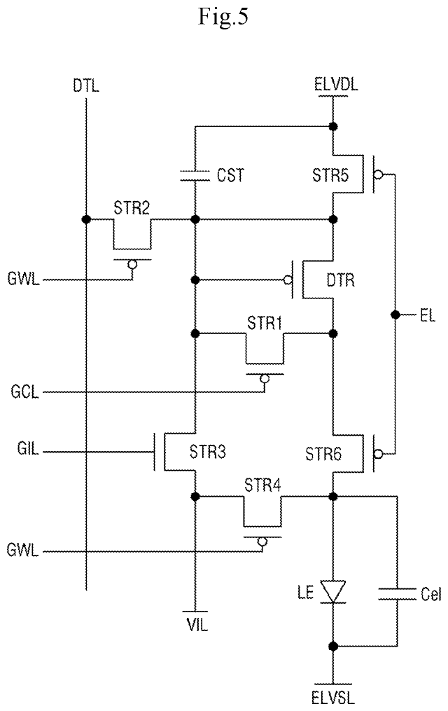

FIG. 5 is a schematic diagram of an equivalent circuit of one-pixel of a display device according to an embodiment.

The embodiment of FIG. 5 differs from the embodiment of FIG. 4 in that the driving transistor DTR, the second transistor STR2, the fourth transistor STR4, the fifth transistor STR5, and the sixth transistor STR6 are formed as the P-type MOSFET, and the first transistor STR1 and the third transistor STR3 are formed as the N-type MOSFET.

Referring to FIG. 5, the active layer of each of the driving transistor DTR, second transistor STR2, fourth transistor STR4, fifth transistor STR5, and sixth transistor STR6 formed as the P-type MOSFET may be formed of polysilicon, and the active layer of each of the first transistor STR1 and third transistor STR3 formed as the N-type MOSFET may be formed of an oxide semiconductor.

FIG. 5 differs from the embodiment of FIG. 4 in that the gate electrode of the second transistor STR2 and the gate electrode of the fourth transistor STR4 are connected to the write scan line GWL, and the gate electrode of the first transistor ST1 is connected to the control scan ling GCL. Also, in FIG. 5, the first transistor STR1 and the third transistor STR3 are formed as the N-type MOSFET, so that the scan signal of the gate high voltage may be applied to the control scan line GCL and the initialization scan line GIL. On the other hand, since the second transistor STR2, the fourth transistor STR4, the fifth transistor STR5, and the sixth transistor STR6 are formed as the P-type MOSFET, the scan signal with a gate low voltage may be applied to the write scan wire GWL and the light emitting element LE.

It should be noted that the equivalent circuit diagram of a pixel according to an embodiment described above is not limited to that shown in FIGS. 3 to 5. The equivalent circuit diagram of a pixel according to an embodiment of the disclosure may be formed by other selected circuit structures that may be employed by those skilled in the art other than the embodiments shown in FIGS. 3 to 5.

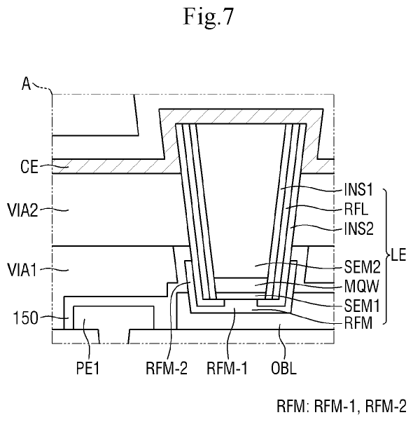

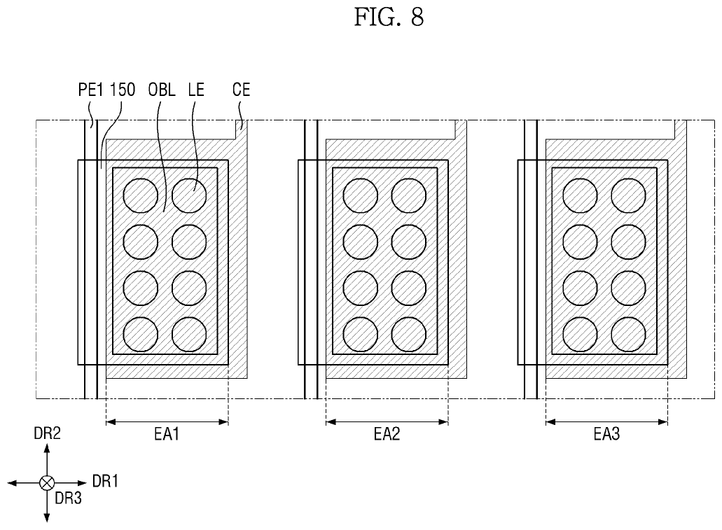

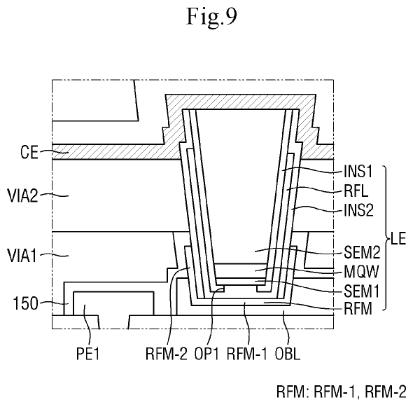

FIG. 6 is a schematic cross-sectional view of a display device according to one embodiment. FIG. 7 is an enlarged view of area A of FIG. 6. FIG. 8 is a schematic plan view illustrating light emitting areas of the display device. FIG. 9 is an enlarged view of area A according to an embodiment.

Referring to FIG. 6, the display device 10 may include a display substrate 100, a wavelength control unit 200 (or controller) and a color filter layer CFL disposed on the display substrate 100.

The display substrate 100 may include a substrate 110 and a light emitting element part LEP disposed on the substrate 110. The substrate 110 may be an insulating substrate. The substrate 110 may include a transparent material. For example, the substrate 110 may include a transparent insulating material such as glass, quartz, or the like within the spirit and the scope of the disclosure. The substrate 110 may be a rigid substrate. However, the substrate 110 is not limited thereto and may include a plastic, such as polyimide, or the like within the spirit and the scope of the disclosure. Also, the substrate 110 may have flexible characteristics that allow it to be warped, bent, folded, or rolled. Emitting areas EA1, EA2, and EA3 and non-emitting areas NEA may be defined on the substrate 110.

Switching elements T1, T2, and T3 may be disposed on the substrate 110. In one embodiment, the first switching element T1 may be disposed in the first light emitting area EA1 of the substrate 110, the second switching element T2 may be disposed in the second light emitting area EA2, and the third switching element T3 may be disposed in the third light emitting area EA3. However, it is not limited to this, and at least one of the first switching clement T1, the second switching element T2, and the third switching element T3 may be disposed in the non-emitting area NEA in other embodiments.

In one embodiment, the first switching element T1, the second switching element T2, and the third switching element T3 may each be a thin film transistor including an amorphous silicon, polysilicon, or oxide semiconductor. Although not shown, there may be signal lines (for example, gate lines, data lines, power supply lines, etc.) further disposed on the substrate 110 that carry signals to each switching element.

Each switching element T1, T2, and T3 may include a semiconductor layer 65, a gate electrode 75, a source electrode 85a, and a drain electrode 85b. For example, a buffer layer 60 may be disposed on the substrate 110. The buffer layer 60 may be disposed to cover a front side of the substrate 110. The buffer layer 60 may include a silicon nitride, a silicon oxide, or a silicon oxynitride, and may be a single layer or a double layer thereof.

The semiconductor layer 65 may be disposed on the buffer layer 60. The semiconductor layer 65 may form a channel of each of the switching elements T1, T2, and T3. The semiconductor layer 65 may include amorphous silicon, polycrystalline silicon, or an oxide semiconductor. In one example, the oxide semiconductor, for example, may include a binary compound (ABx), a ternary compound (ABxCy), or a tetracyclic compound (ABxCyDz) containing indium, zinc, gallium, tin, titanium, aluminum, hafnium (Hf), zirconium (Zr), magnesium (Mg), and the like within the spirit and the scope of the disclosure. In one embodiment, the semiconductor layer 65 may include indium tin zinc oxide (IGZO).

A gate insulating layer 70 may be disposed on the semiconductor layer 65. The gate insulating layer 70 may include a silicon compound, a metal oxide, or the like within the spirit and the scope of the disclosure. For example, the gate insulating layer 70 may include a silicon oxide, a silicon nitride, a silicon oxynitride, an aluminum oxide, a tantalum oxide, a hafnium oxide, a zirconium oxide, a titanium oxide, and the like within the spirit and the scope of the disclosure. In one embodiment, the gate insulating layer 70 may include a silicon oxide.

The gate electrode 75 may be disposed on the gate insulating layer 70. The gate electrode 75 may overlap the semiconductor layer 65. The gate electrode 75 may include a conductive material. The gate electrode 75 may include a metal oxide such as ITO, IZO, ITZO, In₂O₃, or a metal such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be formed of a Cu/Ti double layer in which an upper layer of copper is stacked on a lower layer of titanium but is not limited thereto.

A first interlayer insulating layer 80 and a second interlayer insulating layer 82 may be disposed on the gate electrode 75. The first interlayer insulating layer 80 may be directly disposed on the gate electrode 75, and the second interlayer insulating layer 82 may be directly disposed on the first interlayer insulating layer 80. The first interlayer insulating layer 80 and the second interlayer insulating layer 82 each may include an inorganic insulating material such as a silicon oxide, a silicon nitride, a silicon oxynitride, a hafnium oxide, an aluminum oxide, a titanium oxide, a tantalum oxide, a zinc oxide, and the like within the spirit and the scope of the disclosure. However, it is not limited thereto, and the second interlayer insulating layer 82 may include an organic insulating material capable of flattening a lower step.

The source electrode 85a and a drain electrode 85b may be disposed on the second interlayer insulating layer 80. The source electrode 85a and the drain electrode 85b may be connected to the semiconductor layer 65 through contact holes penetrating the first interlayer insulating layer 80, the second interlayer insulating layer 82, and the gate insulating layer 70, respectively. The source electrode 85a and the drain electrode 85b may include metal oxides such as ITO, IZO, ITZO, In₂O₃, or metals such as copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be formed of a Cu/Ti double layer in which an upper layer of copper is stacked on a lower layer of titanium but is not limited thereto.

A first planarization layer 120 may be disposed on the first switching element T1, the second switching element T2, and the third switching element T3. The first planarization layer 120 may include an organic material. For example, the first planarization layer 120 may include an acrylic resin, an epoxy resin, an imide resin, an ester resin, or the like within the spirit and the scope of the disclosure. In one embodiment, the first planarization layer 120 may include a positive photosensitive material or a negative photosensitive material.

A pixel connection electrode 125 may be disposed on the first planarization layer 120. The pixel connection electrode 125 is disposed to correspond to each of the first switching element T1, the second switching element T2, and the third switching element T3, and may be electrically connected to them. The pixel connection electrode 125 may connect pixel electrodes PE1, PE2, and PE3 described later to the switching elements T1, T2, and T3 described above. The pixel connection electrode 125 may contact the switching elements T1, T2, and T3 through a contact hole penetrating the first planarization layer 120.

A second planarization layer 130 may be disposed on the first planarization layer 120 and the pixel connection electrode 125. The second planarization layer 130 flattens the lower step and may include the same material as the first planarization layer 120 described above.

The light emitting element part LEP may be disposed on the second planarization layer 130. The light emitting element part LEP may include pixel electrodes PE1, PE2, and PE3, organic pattern layers OBL, light emitting elements LE, and a common electrode CE. Also, the light emitting element part LEP may further include a first via layer VIA1 and a second via layer VIA2.

The pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may be electrically connected to the light emitting element LE through a connection electrode 150. The first pixel electrode PE1, the second pixel electrode PE2, and the third pixel electrode PE3 may serve as the first electrode of the light emitting element LE and may be an anode electrode or a cathode electrode. The pixel electrodes PE1, PE2, and PE3 may be disposed in the non-emitting area NEA. The pixel electrodes PE1, PE2, and PE3 may not overlap the emitting areas EA1, EA2, and EA3.

Each of the pixel electrodes PE1, PE2, and PE3 may be directly connected to the pixel connection electrode 125 through the contact hole penetrating the second planarization layer 130 and may be electrically connected to each of the switching elements T1, T2, and T3 through the pixel connection electrode 125. The first pixel electrode PE1, the second pixel electrode PE2, and the third pixel electrode PE3 may include metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Also, the first pixel electrode PE1, the second pixel electrode PE2, and the third pixel electrode PE3 may have a multilayer structure in which two or more metal layers may be stacked each other. For example, the first pixel electrode PE1, the second pixel electrode PE2, and the third pixel electrode PE3 may have a two-layer structure in which a copper layer is stacked on a titanium layer but is not limited thereto.

The organic pattern layers OBL are disposed adjacent to the pixel electrode PE1 and may be disposed in the emitting areas EA1, EA2, and EA3. The organic pattern layers OBL may be formed to be thicker than the pixel electrode. The organic pattern layers OBL may be disposed in a substantially island pattern shape in each light emitting area EA1, EA2, and EA3. For example, the organic pattern layers OBL disposed in each light emitting area EA1, EA2, and EA3 may be disposed apart from the organic pattern layers OBL disposed in adjacent light emitting areas EA1, EA2, and EA3.

A thickness of the organic pattern layers OBL may be about 2 μm or less but is not limited thereto.

The organic pattern layers OBL may include an organic material. The organic material may be, for example, a photosensitive organic insulating material but is not limited thereto. Also, the organic material may include an epoxy-based resin, an acrylic-based resin, a cardo-based resin, or an imide-based resin.

The organic pattern layers OBL may be formed through various methods such as an organic imprinting method, an inkjet printing method, an electro-spray method, or a stamp method.

As in the display device 10 in one embodiment, it is difficult to substitute an anisotropic conductive film (ACF) for an organic pattern layer OBL in a high-resolution display panel.

The light emitting elements LE may be disposed on the organic pattern layers OBL.

As shown in FIGS. 6 to 8, the light emitting elements LE may be disposed in each of the first light emitting area EA1, the second light emitting area EA2, and the third light emitting area EA3. The light emitting element LE may be a vertical light emitting diode clement extending long in the third direction DR3. For example, the length of the light emitting clement LE in the third direction DR3 may be longer than that in the horizontal direction. The length in the horizontal direction refers to the length of the first direction DR1 or the length of the second direction DR2. For example, the length of the light emitting element LE in the third direction DR3 may be in a range of about 1 μm to about 5 μm. However, it is not limited thereto, and the length of the light emitting element LE in the third direction DR3 may be equal to or less than the length in the horizontal direction.

The light emitting clement LE may be a micro light emitting diode element. The light emitting element LE may include a contact electrode RFM, a first semiconductor layer SEM1, an active layer MQW, and a second semiconductor layer SEM2 in the thickness direction of the substrate 110, for example, in the third direction DR3. The contact electrode RFM, the first semiconductor layer SEM1, the active layer MQW, and the second semiconductor layer SEM2 may be sequentially stacked each other in the third direction DR3. The light emitting element LE may include a first insulating layer INS1, a reflective layer RFL, and a second insulating layer INS2 surrounding outer surfaces of the first semiconductor layer SEM1, the active layer MQW, and the second semiconductor layer SEM2.

The light emitting element LE may have a cylindrical shape, a disk shape, or a rod shape where the height is longer than the width. However, the light emitting element LE is not limited thereto, and may have a shape such as a rod, a wire, a tube, a polygonal column shape such as a regular hexahedron, a rectangular parallelepiped, a hexagonal column, or a shape extending in one direction or a direction but having a partially inclined outer surface.

The contact electrode RFM may be disposed on one end of the light emitting element LE and may be disposed on the organic pattern layers OBL. In the following, the light emitting clement LE of the first light emitting area EA1 will be described as an example, but is not limited thereto, and the light emitting element LE disposed on the second pixel electrode PE2 and the third pixel electrode PE3 may have the same structure.

At least a portion of the contact electrode RFM is buried inside the organic pattern layer OBL, and at least a portion of the contact electrode RFM is exposed to the outside without being buried inside the organic pattern layer OBL.

In one embodiment, the contact electrode RFM may include a first portion RFM-1 disposed on one surface or a surface of the light emitting element LE, and a second portion RFM-2 extending from the first portion RFM-1 and disposed on at least a portion of a side surface of the light emitting element LE. The first portion RFM-1 is disposed on the first semiconductor layer SEM1 and may directly contact the first semiconductor layer SEM1. The first portion RFM-1 is buried inside the organic pattern layer OBL and is not visible from the outside of the organic pattern layer OBL. The second portion RFM-2 may surround at least one side or a side of the light emitting element LE. For example, the second portion RFM-2 may surround at least a portion of the first semiconductor layer SEM1, the active layer MQW, and the second semiconductor layer SEM2 but is not limited thereto. In another modification, the second portion RFM-2 surrounds the first semiconductor layer SEM1 and the active layer MQW, and one end of the second portion RFM-2 may coincide with the height of the upper surface of the active layer MQW.

At least a portion of the second portion RFM-2 is exposed to the outside without surrounding at least a portion of the first semiconductor layer SEM1, the active layer MQW, and the second semiconductor layer SEM2. The second portion RFM-2 exposed to the outside without being buried inside the organic pattern layer OBL is electrically connected to the pixel electrode PE through the connection electrode 150 as will be described later.

The contact electrode RFM may include a metal material having conductivity and high light reflectivity but is not limited thereto. The contact electrode RFM may include, for example, at least one of gold (Au), copper (Cu), tin (Sn), silver (Ag), aluminum (Al), and titanium (Ti).

The first semiconductor layer SEM1 may be disposed on the contact electrode RFM. The first reflective layer SEM1 may be disposed adjacent to the first pixel electrode PE1. The first semiconductor layer SEM1 may be a p-type semiconductor and may include a semiconductor material having a chemical formula of AlxGayIn1−x−yN (0≤x≤1,0≤y≤1,0≤x+y≤1). For example, it may be any one or more of p-type doped AlGaInN, GaN, AlGaN, InGaN, AlN, and InN. The first semiconductor layer SEM1 may be doped with a p-type dopant, and the p-type dopant may be Mg, Zn, Ca, Se, Ba, or the like within the spirit and the scope of the disclosure. For example, the first semiconductor layer SEM1 may be p-GaN doped with p-type Mg. The thickness of the first semiconductor layer SEM1 may range from 30 nm to 200 nm but is not limited thereto.

The active layer MQW may be disposed on the first semiconductor layer SEM1. The active layer MQW may emit light by combining electron-hole pairs according to electrical signals applied through the first semiconductor layer SEM1 and the second semiconductor layer SEM2. The active layer MQW may emit first light having a central wavelength range of about 450 nm to about 495 nm, for example, light in a blue wavelength band.

The active layer MQW may include a single or multiple quantum well structure. If the active layer may include a material with a multi-quantum well structure, it may be a stacked structure with well layers and a barrier layer alternating with each other. The well layer may be formed of InGaN and the barrier layer may be formed of GaN or AlGaN, but is not limited thereto. The thickness of the well layer may be in a range of about 1 nm to about 4 nm, and the thickness of the barrier layer may be in a range of about 3 nm to about 10 nm.

For example, the active layer MQW may have a structure in which a semiconductor material having a large band gap energy and a semiconductor material having a small band gap energy are alternately stacked with each other and may include other Group 3 to Group 5 semiconductor materials depending on the wavelength band of the emitted light. The light emitted from the active layer MQW is not limited to the first light and may emit second light (light of a green wavelength band) or third light (light of a red wavelength band) according to circumstances. In one embodiment, in case that indium is included among the semiconductor materials included in the active layer MQW, the color of emitted light may vary according to the amount of indium. For example, in case that the indium content is about 15%, the light in a blue wavelength band may be emitted, in case that the indium content is about 25%, the light in a green wavelength band may be emitted, and in case that the indium content is about 35% or more, the light in a red wavelength band may be emitted.

The second semiconductor layer SEM2 may be disposed on the active layer MQW. The second semiconductor layer SEM2 may be the n-type semiconductor. The second semiconductor layer SEM2 may include a semiconductor material having the formula AlxGayIn1−x−yN (0≤x≤1,0≤y≤1, 0x+y≤1). For example, it may be one or more of n-type doped AlGaInN, GaN, AlGaN, InGaN, AlN, and InN. The second semiconductor layer SEM2 may be doped with an n-type dopant, and the n-type dopant may be Si, Ge, Sn, or the like within the spirit and the scope of the disclosure. For example, the second semiconductor layer SEM2 may be n-GaN doped with n-type Si. The thickness of the second semiconductor layer SEM2 may range from about 2 μm to about 4 μm but is not limited thereto.

The first insulating layer INS1 may surround side surfaces of the light emitting clement LE, for example, an outer circumferential surface. The first insulating layer INS1 may insulate the light emitting elements LE from other layers. The first insulating layer INS1 may be directly disposed on the outer circumferential surfaces of the first semiconductor layer SEM1, the second semiconductor layer SEM2, and the active layer MQW to surround them. In one embodiment, the first insulating layer INS1 may surround the entire outer circumferential surfaces of the first semiconductor layer SEM1, the active layer MQW, and the second semiconductor layer SEM2.

As shown in FIG. 7, the first insulating layer INS1 may be disposed to surround the light emitting elements LE. The first insulating layer INS1 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), and the like within the spirit and the scope of the disclosure. The thickness of the first insulating layer INS1 may be about 0.1 μm but is not limited thereto.

The reflective layer RFL may be disposed on the first insulating layer INS1. The reflective layer RFL may directly contact one surface or a surface of the first insulating layer INS1. The reflective layer RFL may be disposed to surround a side surface of the light emitting element LE. For example, the reflective layer RFL surrounds the outer circumferential surface of the light emitting element LE on the first insulating layer INS1 and may surround side surfaces of the first semiconductor layer SEM1, the active layer MQW, and the second semiconductor layer SEM2 of the light emitting element LE1. The reflective layer RFL may surround the side surfaces of the first semiconductor layer SEM1 and the active layer MQW of the light emitting element LE and may surround at least a portion of the side surfaces of the second semiconductor layer SEM2. The height of the reflective layer RFL may be substantially the same as that of the first insulating layer INS1. Here, the height of the reflective layer RFL and the height of the first insulating layer INS1 may mean heights from the upper surface of the contact electrode RFM to the highest point in the thickness direction.

In an embodiment with reference to FIG. 9, the height of the reflective layer RFL may be lower than that of the first insulating layer INS1. For example, the height of the reflective layer RFL may be lower than that of the light emitting element LE. The reflective layer RFL may be completely surrounded by the first insulating layer INS1 and the second insulating layer INS2. For example, the reflective layer RFL may be insulated from the outside by the first insulating layer INS1 and the second insulating layer INS2.

The reflective layer RFL may reflect light emitted from the light emitting element LE. For example, the reflective layer RFL may reflect light emitted from the active layer MQW of the light emitting element LE to the side upward (e.g., in the third direction DR3. For example, the reflective layer RFL may improve the light emitting efficiency of the light emitting clement LE. To this end, the reflective layer RFL may be disposed to surround at least a side surface of the active layer MQW of the light emitting element LE.

The reflective layer RFL may include a metal material having high reflectivity. For example, the reflective layer RFL may include aluminum or silver, or may be an alloy thereof.

The second insulating layer INS2 may be disposed on the reflective layer RFL. The second insulating layer INS2 may directly contact one surface or a surface of the reflective layer RFL. The second insulating layer INS2 may be disposed to surround a side surface of the light emitting element LE. For example, the second insulating layer INS2 surrounds the outer circumferential surface of the light emitting element LE on the reflective layer RFL and may surround side surfaces of the first semiconductor layer SEM1, the active layer MQW, and the second semiconductor layer SEM2 of the light emitting element LE1.

The second insulating layer INS2 covers one end or an end of the reflective layer RFL and one end of the first insulating layer INS1, so that one end of the reflective layer RFL and the first insulating layer INS1 may not directly contact the contact electrode RFM. The reflective layer RFL may be disposed between the first insulating layer INS1 and the second insulating layer INS2 and may be insulated from the contact electrode RFM by the second insulating layer INS2.

The connection electrode 150 may cover the pixel electrode PE and may extend along the side surface and upper surface of the organic pattern layer OBL on which the light emitting element LE is not disposed and along the side surface and upper surface of the contact electrode RFM. The connection electrode 150 may cover all the second portion RFM-2 exposed to the outside of the organic pattern layer OBL. Accordingly, the height of the connection electrode 150 may be higher than that of the contact electrode RFM. The connection electrode 150 may be disposed to surround the first semiconductor layer SEM1, the active layer MQW, and the second semiconductor layer SEM2 on the second portion RFM-2.

The connection electrode 150 may overlap each of the light emitting areas EA1, EA2, and EA3 and the non-emitting area NEA, but the adjacent connection electrodes 150 may be spaced apart from each other. The connection electrode 150 may include holes disposed in regions corresponding to the light emitting elements LE on a plane.

The connection electrode 150 electrically connects the pixel electrode PE and the light emitting element LE. Therefore, the light emitting element LE is not disposed on and does not directly contact the pixel electrode PE. The light emitting element LE contacts the pixel electrode PE at the side through the connection electrode 150.

The connection electrode 150 may include a metal material having low resistance such as aluminum (Al), silver (Ag), or copper (Cu) or a metal oxide such as ITO, IZO, or ITZO.

The connection electrode 150 may serve to transfer a light emitting signal from the first pixel electrode PE1 to the light emitting element LE.

The first via layer VIA1 may be disposed on the connection electrode 150. The first via layer VIA1 may prevent lower components from being damaged in an etching process of the light emitting element LE, which will be described later. For example, the first via layer VIA1 may protect the lower connection electrode 150. The first via layer VIA1 may contact the upper surface of the connection electrode 150 and cover the connection electrode 150. The first via layer VIA1 covers the connection electrode 150 and may have a selectable height. For example, the height of the first via layer VIA1 may be equal to or higher than the highest height of the connection electrode 150.

The first via layer VIA1 may include an organic material to flatten the lower step. For example, the first via layer VIA1 may include a polyacrylates resin, an epoxy resin, a phenolic resin, a polyamides resin, a polyimides rein, unsaturated polyesters resin, poly phenylenethers resin, polyphenylenesulfides resin, or benzocyclobutene (BCB).

The second via layer VIA2 may be disposed on the first via layer VIA1. The second via layer VIA2 may cover the first via layer VIA1 and may flatten a step at the bottom to allow the common electrode CE to be formed, as described later. The second via layer VIA2 may be formed at a selectable height such that at least a portion of the light emitting elements LE, for example, the second semiconductor layer SEM2 may protrude above the second via layer VIA2. In other words, the height of the second via layer VIA2 may be smaller than the height of the light emitting element LE.

The second via layer VIA2 may cover the first via layer VIA1 to protect them.

The common electrode CE may be disposed on the second via layer VIA2 and the light emitting elements LE. For example, the common electrode CE may be disposed on one surface or a surface of the substrate 110 on which the light emitting element LE is formed. The common electrode CE is disposed to overlap each of the light emitting areas EA1, EA2, and EA3 and the non-emitting area NEA, and may be made of a thin thickness to allow light to be emitted.

The common electrode CE may be directly disposed on top and side surfaces of the light emitting elements LE.

The common electrode CE may be directly disposed on top and side surfaces of the light emitting elements LE. The common electrode CE may directly contact the second semiconductor layer SEM2 exposed on the upper surface of the light emitting element LE. As shown in FIG. 6, the common electrode CE may be a common layer covering the light emitting elements LE and disposed in common connection with the light emitting elements LE. Since the conductive second semiconductor layer SEM2 has a patterned structure in each light emitting element LE, the common electrode CE may directly contact the second semiconductor layer SEM2 of each light emitting element LE so that a common voltage may be applied to each light emitting element LE.

The common electrode CE may include a material having a low resistance as it is disposed throughout the substrate 110 to which the common voltage is applied. Also, the common electrode CE may be formed to have a thin thickness to readily transmit light. For example, the common electrode CE may include a low-resistance metal material such as aluminum (Al), silver (Ag), copper (Cu), or the like, or a metal oxide such as ITO, IZO, ITZO, or the like within the spirit and the scope of the disclosure. The common electrode CE may have a thickness in a range of about 10 Å to about 200 Å but is not limited thereto.

The light emitting elements LE described above may be supplied with a pixel voltage or an anode voltage from each of the pixel electrodes PE1, PE2, and PE3 and the common voltage through the common electrode CE. The light emitting elements LE may emit light with a selectable luminance according to a voltage difference between the pixel voltage and the common voltage. In one embodiment, the disadvantages of organic light emitting diodes, which are vulnerable to external moisture or oxygen, may be excluded and the life and reliability may be improved by disposing light emitting elements LE, for example, inorganic light emitting diodes, on the pixel electrodes PE1, PE2, and PE3.

As shown in FIG. 8, the light emitting elements LE may be disposed on the organic pattern layer OBL. The light emitting elements LE arranged in a regular pattern with some regularity. For example, the light emitting elements LE may be spaced apart from each other at regular intervals. In one embodiment, 2×4 light emitting elements are disposed on one organic pattern layer OBL, but it is not limited thereto, and various modifications such as 2×3 and 1×4, etc. may be considered.

The light emitting element part LEP may further include a first capping layer CPL1 covering the common electrode CE. The first capping layer CPL1 may be directly disposed on the common electrode CE. The first capping layer CPL1 serves to protect components disposed below, for example, the light emitting elements LE and the common electrode CE, from moisture or debris by covering them.

The first capping layer CPL1 may include an inorganic material. For example, the first capping layer CPL1 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxide. Although the drawing illustrates that the first capping layer CPL1 is formed of one layer, it is not limited thereto. For example, the first capping layer CPL1 may be formed as multiple layers stacked with alternating inorganic layers including at least one of the materials, for example, materials that the first capping layer CPL1 may include. The thickness of the first capping layer CPL1 may range from about 0.05 μm to about 2 μm but is not limited thereto.

The wavelength control unit 200 (or controller) may be disposed on the light emitting element part LEP. The wavelength control unit 200 (or controller) may include a first wavelength conversion layer WCL1, a second wavelength conversion layer WCL2, and a light transmitting layer TPL. Also, the wavelength control unit 200 (or controller) may further include a bank layer BNL.

The bank layer BNL is disposed on the first capping layer CPL1 and may partition light emitting areas EA1, EA2, and EA3. The bank layer BNL is disposed to extend in the first and second directions DR1 and DR2 and may be formed in a lattice pattern throughout the display area DPA. Also, the bank layer BNL does not overlap the emitting areas EA1, EA2, and EA3 and may overlap the non-emitting area NEA.

The bank layer BNL may serve to provide a space in which the first wavelength conversion layer WCL1, the second wavelength conversion layer WCL2, and the light transmitting layer TPL are formed. To this end, the bank layer BNL may have a thickness in a range of about 1 μm to about 10 μm. The bank layer BNL may include an organic insulating material to be formed with a large thickness. The organic insulating material may include, for example, an epoxy-based resin, an acrylic-based resin, a cardo-based resin, or an imide-based resin.

In one embodiment, the bank layer BNL may further include a light blocking material and may include a dye or pigment having light blocking properties. For example, the bank layer BNL may be a black matrix. External light incident from the outside of the display device 10 may cause a problem of distorting the color gamut of the wavelength control unit 200 (or controller). According to an embodiment, color distortion due to reflection of external light may be reduced by disposing the bank layer BNL including the light blocking material in the wavelength control unit 200 (or controller). The bank layer BNL including the light blocking material may prevent light from penetrating between adjacent light emitting areas and thus color mixing, thereby further improving color reproducibility.

The first wavelength conversion layer WCL1, the second wavelength conversion layer WCL2, and the light transmitting layer TPL may be disposed on the emitting areas EA1, EA2, and EA3. The first wavelength conversion layer WCL1 and the second wavelength conversion layer WCL2 may convert or shift the peak wavelength of incident light into another specific peak wavelength and emit the light. The first wavelength conversion layer WCL1 converts blue light emitted from the light emitting element LE into red light, and the second wavelength conversion layer WCL2 converts blue light into green light. The light transmission layer TP may transmit blue light as it is.

The first wavelength conversion layer WCL1, the second wavelength conversion layer WCL2, and the light transmitting layer TPL may be disposed in each of the light emitting areas EA1, EA2, and EA3 partitioned by the bank layer BNL, and may be arranged spaced apart from each other. For example, the first wavelength conversion layer WCL1, the second wavelength conversion layer WCL2, and the light transmitting layer TPL may be formed in a dot-shaped island pattern spaced apart from each other.

The first wavelength conversion layer WCL1 may be disposed to overlap the first emitting area EA1. The first wavelength conversion layer WCL1 may convert or shift a peak wavelength of incident light into light having another specific peak wavelength and emit the light. In an embodiment, the first wavelength conversion layer WCL1 may convert blue light emitted from the light emitting element LE of the first light emitting area EA1 into red light having a single peak wavelength in the range of about 610 nm to about 650 nm and emits the red light.

The first wavelength conversion layer WCL1 may include a first base resin BRS1, first wavelength conversion particles WCP1, and scatterers SCP. The first base resin BRS1 may include a light-transmitting organic material. For example, the first base resin BRS1 may include an epoxy-based resin, an acrylic-based resin, a cardo-based resin, or an imide-based resin.

The first wavelength conversion particle WCP1 may convert blue light incident from the light emitting element LE into red light. For example, the first wavelength conversion particle WCP1 may convert light in a blue wavelength band into light in a red wavelength band. The first wavelength conversion particle WCP1 may be a quantum dot (QD), a quantum rod, a fluorescent material, or a phosphorescent material. For example, the quantum dot may be a particulate material that emits a specific color while electrons transition from a conduction band to a valence band.

The quantum dots may be semiconductor nanocrystalline materials. Depending on its composition and size, the quantum dot may have a specific bandgap to absorb light and emit light with a unique wavelength. Examples of the semiconductor nanocrystals of the quantum dots include IV group nanocrystals, II-VI group compound nanocrystals, III-V group compound nanocrystals, IV-VI group nanocrystals, or combinations thereof.

The group II-VI compound is a binary compound selected from the group consisting of CdSe, CdTe, ZnS, ZnSe, ZnTe, ZnO, HgS, HgSe, HgTe, MgSe, MgS, and mixtures thereof; InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and ternary compounds selected from the group consisting of mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group III-V compound is a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The group IV-VI compounds may be selected from the group consisting of binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The group IV element may be selected from the group consisting of Si, Ge, and mixtures thereof. The group IV compound may be a binary compound selected from the group consisting of SiC, SiGe, and mixtures thereof.

The binary, ternary, or quaternary compounds may be present in the particle at a uniform concentration or may be present in the same particle with a partially different concentration distribution. The quantum dot may also have a core/shell structure in which one quantum dot surrounds another. The interface of the core and shell may have a concentration gradient where the concentration of an element present in the shell decreases toward the center.

In one embodiment, the quantum dot may have a core-shell structure including a core including a nanocrystal as described above and a shell surrounding the core. The shell of the quantum dot may act as a protective layer to prevent chemical denaturation of the core to maintain semiconductor properties and/or as a charging layer to impart electrophoretic properties to the quantum dot. The shell may be monolayer or multilayer. Examples of shells for the quantum dots include oxides of metals or non-metals, semiconductor compounds, or combinations thereof.

For example, the oxides of said metals or non-metals may be, for example, binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds such as MgAl₂O₄, CoFe₂O₄, NiFe₂O₄, CoMn₂O₄, but the disclosure is not limited thereto.

The semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, etc but are not limited thereto.

The scatterer SCP may scatter the light of the light emitting element LE in a random direction. The scatterer SCP may have a refractive index different from that of the first base resin BRS1 and form an optical interface with the first base resin BRS1. For example, the scatterer SCP may be a light scattering particle. The scatterer SCP is not particularly limited to any material capable of scattering at least a portion of the transmitted light, but may be, for example, metal oxide particles or organic particles. Examples of the metal oxide include titanium oxide (TiO₂), zirconium oxide (ZrO₂), aluminum oxide (Al₂O₃), indium oxide (In₂O₃), zinc oxide (ZnO), tin oxide (SnO₂), and the like, and examples of organic particle materials include acrylic resins or urethane resins. The scatterer SCP may scatter light in the random direction regardless of the incident direction of incident light without substantially converting the wavelength of light.

The second wavelength conversion layer WCL2 may be disposed to overlap the second emission area EA2. The second wavelength conversion layer WCL2 may convert or shift the peak wavelength of incident light into light having another specific peak wavelength and emit the light. In one embodiment, the second wavelength conversion layer WCL2 may convert blue light emitted from the light emitting element LE of the second light emitting area EA2 into green light having the peak wavelength in a range of about 510 nm to about 550 nm and emit it.

The second wavelength conversion layer WCL2 may include a second base resin BRS2 and second wavelength conversion particles WCP2 and scatterers SCP dispersed in the second base resin BRS2.

The second base resin BRS2 may be made of a material having high light transmittance and may be made of the same material as the first base resin BRS1 or may include at least one of the example materials as constituent materials thereof.

The second wavelength conversion particle WCP2 may convert or shift the peak wavelength of incident light to another specific peak wavelength. In one embodiment, the second wavelength conversion particle WCP2 may convert blue light provided from the light emitting element LE into green light having a peak wavelength in a range of about 510 nm to about 550 nm and emit it. Examples of the second wavelength conversion particle WCP2 include quantum dots, quantum rods, or phosphors. A more specific description of the second wavelength conversion particle WCP2 is substantially the same as or similar to that described above in the description of the first wavelength conversion particle WCP1, and thus will be omitted.

The light transmitting layer TPL may be disposed to overlap the third light emitting area EA3. The light transmitting layer TPL may transmit incident light. The light transmitting layer TPL may transmit blue light emitted from the light emitting element LE disposed in the third light emitting area EA3 as it is. The light transmitting layer TPL may include a third base resin BRS3, and scatterers SCP dispersed in the third base resin BRS3. Since the third base resin BRS3 is substantially the same as or similar to the first base resin BRS3 described above, a description thereof will be omitted.

The light transmitted the wavelength control unit 200 (or controller) may implement full color by passing through the color filter layer CFL, which will be described later.

The wavelength control unit 200 (or controller) may further include a second capping layer CPL2. The second capping layer CPL2 covers the first wavelength conversion layer WCL1, the second wavelength conversion layer WCL2, the light transmitting layer TPL, and the bank layer BNL disposed thereunder to protect them from moisture or foreign matter. The second capping layer CPL2 may include an inorganic material and may include a material substantially the same as or similar to that of the first capping layer CPL1 described above.

A first color filter CF1, a second color filter CF2, and a third color filter CF3 may be disposed on the second capping layer CPL2. The first color filter CF1 is disposed in the first light emitting area EA1, the second color filter CF2 is disposed in the second light emitting area EA2, and the third color filter CF3 is disposed in the third light emitting area EA3.

The first color filter CF1, the second color filter CF2, and the third color filter CF3 may include colorants such as dyes or pigments that absorb wavelengths other than the corresponding color wavelengths. The first color filter CF1 may selectively transmit red light and block or absorb blue and green light. The second color filter CF2 may selectively transmit green light and block or absorb blue and red light. The third color filter CF3 may selectively transmit blue light and block or absorb red and green light. For example, the first color filter CF1 may be a red color filter, the second color filter CF2 may be a green color filter, and the third color filter CF3 may be a blue color filter.

In one embodiment, light incident on the first color filter CF1 may be light converted to red light by the first wavelength conversion layer WCL1, and light incident on the second color filter CF2 may be light converted into green light by the second wavelength conversion layer WCL2, and light incident on the third color filter CF3 may be blue light transmitted through the light transmitting layer TPL. As a result, the red light transmitted through the first color filter CF1, the green light transmitted through the second color filter CF2, and the blue light transmitted through the third color filter CF3 may be emitted onto the upper of the substrate 110 to achieve full color.

The first color filter CF1, the second color filter CF2, and the third color filter CF3 may absorb some of the light introduced from the outside of the display device 10 to reduce reflected light caused by external light. Accordingly, the first color filter CF1, the second color filter CF2, and the third color filter CF3 may prevent color distortion due to external light reflection.

The first color filter CF1 is disposed in the non-emitting area NEA, and at least one of the second color filter CF2 and the third color filter CF3 may be further disposed overlapping each other. For example, the first color filter CF1, the second color filter CF2, and the third color filter CF3 may be disposed in the non-emitting area NEA.

Accordingly, light emission from the display device may be blocked in the non-emitting area NEA, and reflection of external light may be suppressed. Each color filter CF1, CF2, and CF3 blocks the emission of light of a color other than the corresponding color of each light emitting area EA1, EA2, and EA3, and accordingly, light of red (R), green (G), and blue (B) colors may all be blocked in the non-emitting area NEA. However, the disclosure is not limited thereto, and a light absorbing member including a light absorbing material that a visible light wavelength band may be disposed in the non-emitting area NEA.

An overcoat layer OC may be disposed on the color filter layer CFL. The overcoat layer OC may be directly disposed on the color filter layer CFL. The overcoat layer OC may be entirely disposed in the display area DPA and may have a flat surface. The overcoat layer OC may flatten a step formed by the lower color filter layer CFL. The overcoat layer OC may include the light-transmitting organic material.

In another modification, in one embodiment, the first light emitting element LE1 disposed in the first light emitting area EA1 may emit a first light of blue color, the second light emitting element LE2 disposed in the second light emitting area EA2 may emit a second light of red color, and the third light emitting element LE3 disposed in the third light emitting area LE3 may emit a third light of green color. In this way, in case that the light emitting elements disposed in different light emitting areas may emit light of different wavelengths, the wavelength control unit 200 (or controller) and the color filter layer CFL described with reference to FIG. 6 may be omitted.

As described above, the display device 10 according to one embodiment may bond the light emitting elements LE to the substrate 110 by placing each light emitting element LE on the organic patterned layer OBL and forming the connecting electrode 150. Accordingly, the eutectic bonding requiring high heat and pressure for the light emitting element LE in the display device 10 may be omitted.

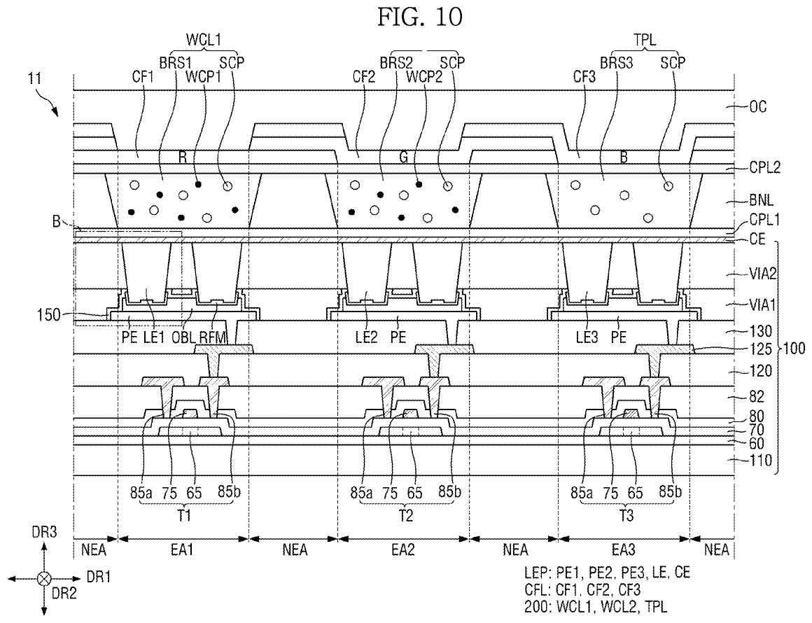

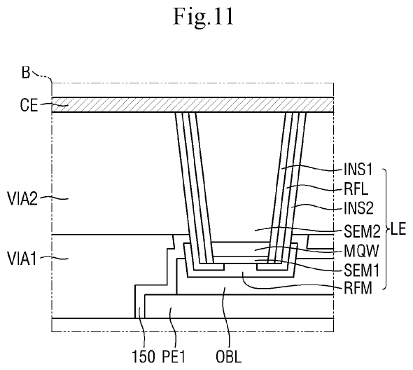

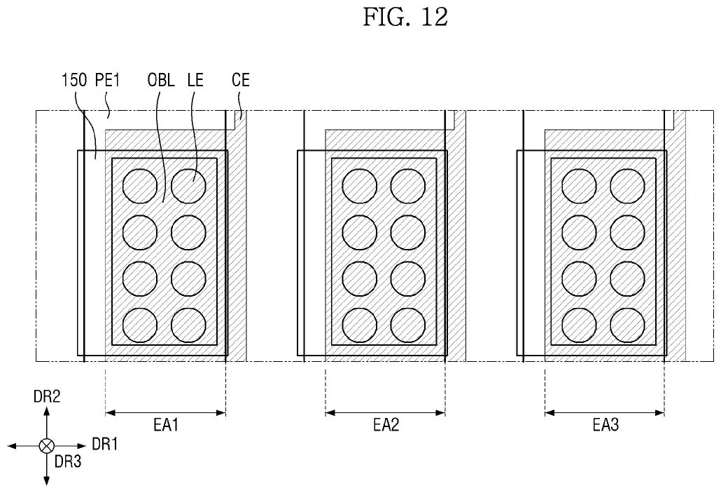

FIG. 10 is a schematic cross-sectional view of a display device 11 according to an embodiment. FIG. 11 is an enlarged view of area B of FIG. 10. FIG. 12 is a schematic plan view illustrating light emitting areas of the display device.

The embodiments of FIGS. 11 and 12 are different from the embodiments of FIGS. 6 to 9 described above in that the pixel electrodes PE1, PE2, and PE3 are disposed in the light emitting areas EA1, EA2, and EA3 and the organic pattern layer OBL is disposed on the pixel electrodes PE1, PE2, and PE3, and the common electrode CE is not disposed on the side of the light emitting element LE. Hereinafter, descriptions overlapping those of the above-described embodiments will be omitted, and differences will be described.

The pixel electrodes PE1, PE2, and PE3 may be disposed in the emitting areas EA1, EA2, and EA3 and in the non-emitting area NEA.

The organic pattern layer OBL may be disposed on the pixel electrodes PEI, PE2, and PE3.

The organic pattern layer OBL may be disposed in an island pattern shape on the pixel electrodes PE1, PE2, and PE3. The planar shape of the organic pattern layer OBL may be similar to that of the pixel electrodes PE1, PE2, and PE3 but may be smaller than the pixel electrodes.

The light emitting element LE is disposed so that one end is buried on the organic pattern layer OBL. A portion of the contact electrode RFM of the light emitting element LE is disposed to be buried in the organic pattern layer OBL, and a portion of the contact electrode RFM of the light emitting element LE is exposed to the outside of the organic pattern layer OBL.

The connection electrode 150 may cover the pixel electrode PE and may extend along the side surface and upper surface of the organic pattern layer OBL on which the light emitting element LE is not disposed and along the side surface and upper surface of the contact electrode RFM.

Accordingly, the connection electrode 150 electrically connects the pixel electrode PE and the light emitting element LE. The light emitting element LE contacts the pixel electrode PE at the side through the connection electrode 150.

The common electrode CE may be disposed on the light emitting element LE and the second via layer VIA2. For example, the common electrode CE is disposed on one surface or a surface of the substrate 110 on which the light emitting element LE is formed and may be formed to have a small thickness so that light may be emitted.

The common electrode CE may be directly disposed on top and side surfaces of the light emitting elements LE. For example, the common electrode CE may contact the second semiconductor layer SEM2, which is the upper surface of the light emitting element LE, and directly contact the reflective layer RF, which is the side surface of the light emitting element LE. The common electrode CE may be a common layer disposed to cover the light emitting elements LE and to connect the light emitting elements LE in common.

Hereinafter, a manufacturing process of the display device 10 according to one embodiment will be described with reference to other drawings.

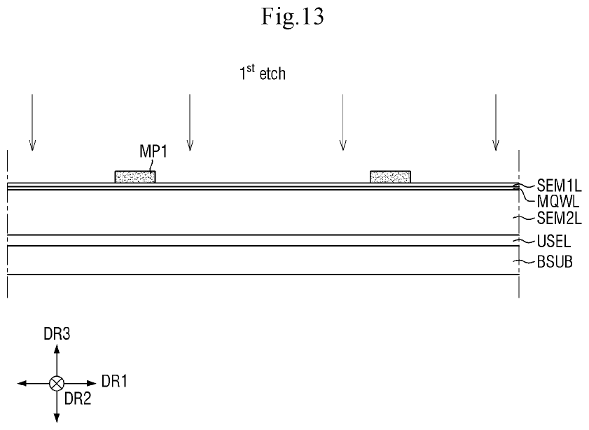

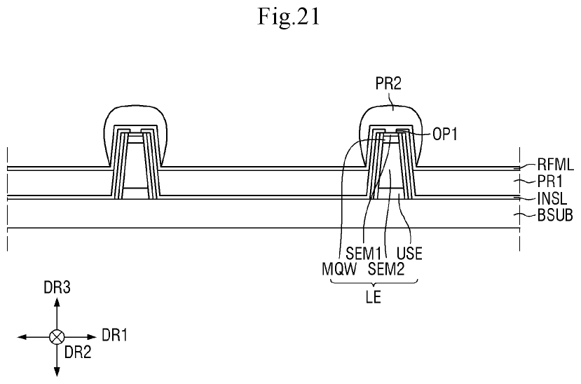

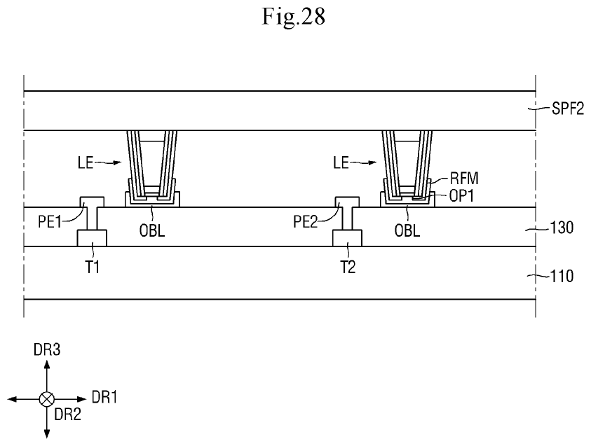

FIGS. 13 to 33 are schematic diagrams for explaining a method of manufacturing a display device according to one embodiment.

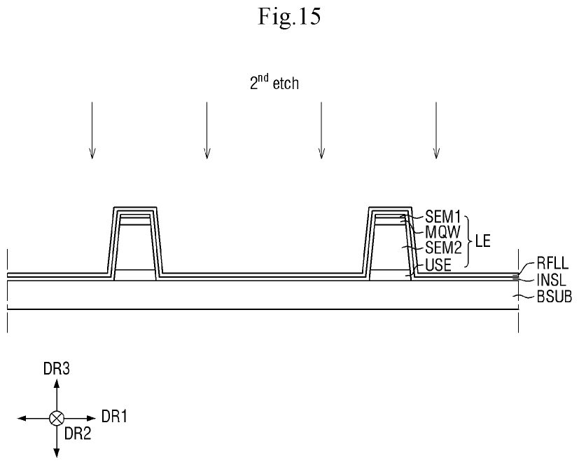

FIGS. 13 to 33 illustrate structures according to the formation order of each layer of the display device 10 as schematic cross-sectional views. FIGS. 15 to 33 show the manufacturing process of the light emitting element part LEP, and these may generally correspond to the schematic cross-sectional view of FIG. 7. Also, the first light emitting area EA1 and the second light emitting area EA2 of the display device 10 are shown in the following. One light emitting element LE is disposed in one light emitting area EA1 for convenience of description but is not limited thereto.

Referring to FIGS. 13 to 22, light emitting elements LE are formed on a base substrate BSUB.

For example, referring to FIG. 13, the base substrate BSUB is prepared. The base substrate BSUB may be a sapphire substrate Al₂O₃ or a silicon wafer including silicon. However, it is not limited thereto, and in one embodiment, a case where the base substrate BSUB is a sapphire substrate will be described as an example.

Semiconductor material layers USEL, SEM2L, MQWL, and SEM1L are formed on the base substrate BSUB. The semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and the like, and, for example, formed by metal organic chemical vapor deposition (MOCVD). However, it is not limited thereto.

A precursor material for forming the semiconductor material layers is not particularly limited within the range that may be selected for forming the subject material. In one example, the precursor material may be a metal precursor including an alkyl group such as a methyl or ethyl group. For example, it may be a compound such as trimethyl gallium (Ga(CH₃)₃), trimethyl aluminum (Al(CH₃)₃), triethyl phosphate ((C₂H₅)₃PO₄) but are not limited thereto.

For example, a third semiconductor material layer USEL is formed on the base substrate BSUB. While the drawings illustrate the third semiconductor material layer USEL being further stacked, it is not limited to this, and layers may be formed. The third semiconductor material layer USEL may be disposed to reduce a lattice constant difference between a second semiconductor material layer SEM2L and the base substrate BSUB. For example, the third semiconductor material layer USEL may include an undoped semiconductor, which may be an n-type or p-type undoped material. In an embodiment, the third semiconductor material layer USEL may be at least one of undoped InAlGaN, GaN, AlGaN, InGaN, AlN, and InN but is not limited thereto.

The second semiconductor material layer SEM2L, the active material layer MQWL, and the first semiconductor material layer SEM1L are sequentially formed on the third semiconductor material layer USEL by using the above-described method.

The semiconductor material layers USEL, SEM2L, MQWL, and SEM1L are etched to form the light emitting elements LE1 and LE3.

For example, first mask patterns MP1 are formed on the first semiconductor material layer SEM1L. The first mask pattern MP1 may be a hard mask including an inorganic material or a photoresist mask including an organic material. The first mask pattern MP1 prevents the lower semiconductor material layers USEL, SEM2L, MQWL, and SEM1L from being etched. A portion of the semiconductor material layers is etched (1^{st} etch) using the first mask patterns MP1 as a mask to form the light emitting elements LE.

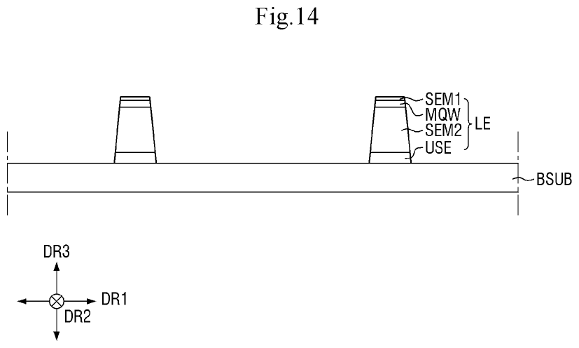

As shown in FIG. 14, on the base substrate BSUB, the semiconductor material layers USEL, SEM2L, MQWL, and SEM1L that are non-overlapping the first mask pattern MP1 are etched and removed, and the portions that are not etched overlapping the first mask pattern MP1 may be formed into the light emitting elements LE.

The semiconductor material layers may be etched by selected methods. For example, the process of etching the semiconductor material layers may be dry etching, wet etching, reactive ion etching (RIE), deep reactive ion etching (DRIE), inductively coupled plasma reactive ion etching (ICP-RIE), and the like within the spirit and the scope of the disclosure. In the case of dry etching methods, anisotropic etching is possible, which may be suitable for vertical etching. In case that utilizing the etching method described above, the etchant may be Cl₂ or O₂. However, it is not limited thereto.

The semiconductor material layers USEL, SEM2L, MQWL, and SEM1L overlapping the first mask pattern MP1 are not etched but are formed into the light emitting elements LE. Thus, the light emitting elements LE are formed including a third semiconductor layer USE, the second semiconductor layer SEM2, the active layer MQW, and the first semiconductor layer SEM1.

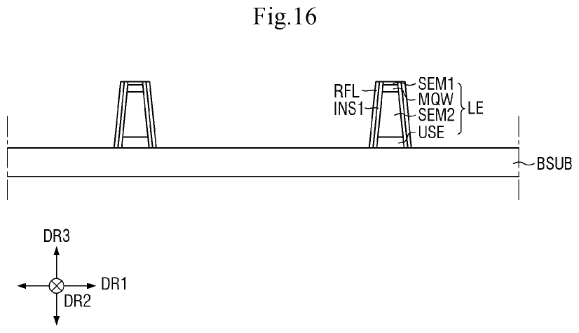

Referring to FIGS. 15 and 16, the first insulating layer INS1 and the reflective layer RFL are formed on the base substrate BSUB on which the light emitting element LE is formed.

For example, an insulating material layer INSL is formed on the outer surfaces of the light emitting elements LE. The insulating material layer INSL may be formed on the entire surface of the base substrate BSUB and may be formed not only on the light emitting element LE, but also on the upper surface of the base substrate BSUB exposed by the light emitting clement LE. Also, a reflective material layer RFLL is formed on the insulating material layer INSL. The reflective material layer RFLL is formed on the entire surface of the base substrate BSUB.

A second etch (2^{nd} etch) is performed to partially remove the insulating material layer INSL to form the light emitting element LE including the first insulating layer INS1 and the reflective layer RFL.

For example, the second etching process may be performed in which a portion of the insulating material layer INSL and the reflective material layer RFLL are partially removed such that the insulating material layer INSL exposes the upper surface of the light emitting element LE but surrounds the sides of the light emitting element LE. For example, a portion of the insulating material layer INSL may be removed to expose the upper surface of the first semiconductor layer SEM1 of the light emitting element LE in this process. The process of partially removing the insulating material layer INSL may be performed by a process such as anisotropic dry etching or etch-back.

In another modification, the insulating material layer INSL is formed on the outer surfaces of the light emitting elements LE, and the insulating material layer INSL is partially removed to form the first insulating layer INS1. Thereafter, the reflective material layer RFLL may be formed on the outer surface of the light emitting elements LE, and the reflective material layer RFLL may be partially removed to form the reflective layer RFL.

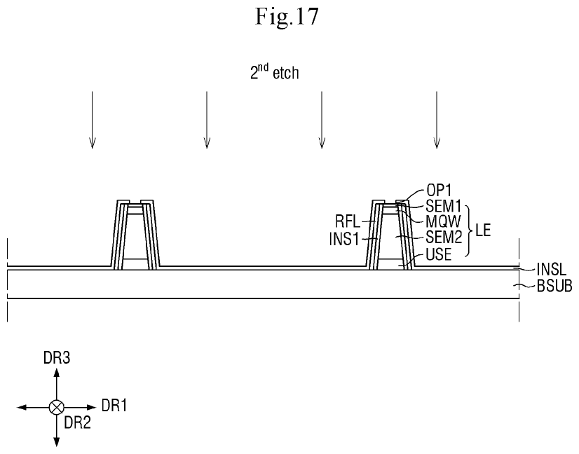

Referring to FIG. 17, the second insulating layer INS2 having a first opening OP1 is formed surrounding the light emitting element LE on which the first insulating layer INS1 and the reflective layer RFL are formed. The first opening OP1 is formed on the upper surface of the light emitting element LE.

The method of forming the second insulating layer INS2 is similar to that of the first insulating layer INS1. For example, the insulating material layer INSL is formed on the outer surfaces of the light emitting elements LE. The insulating material layer INSL may be formed on the entire surface of the base substrate BSUB and may be formed not only on the light emitting element LE, but also on the upper surface of the base substrate BSUB exposed by the light emitting element LE. Subsequently, the etching is performed to partially remove the insulating material layer INSL to form the first insulating layer INS1 having the first opening OP1 on the upper surface of the light emitting element LE. For example, the etching process may be performed to partially remove a portion of the insulating material layer INSL so that the insulating material layer INSL exposes at least a portion of the upper surface of the light emitting element LE while surrounding the side surface of the light emitting element LE. For example, a portion of the insulating material layer INSL may be removed using a mask to expose the first opening OP1 on the upper surface of the first semiconductor layer SEM1 of the light emitting element LE in this process.

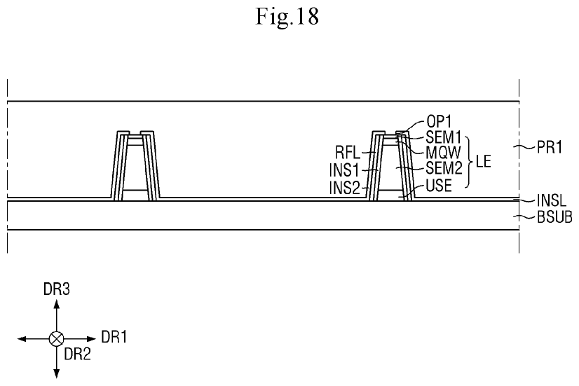

Referring to FIGS. 18 to 22, the contact electrode RFM covering one surface or a surface of the light emitting element LE is formed using a photoresist PR1.

For example, referring to FIG. 18, the first photoresist PR1 is applied to cover the entire upper surface of the light emitting element LE to be planarized.

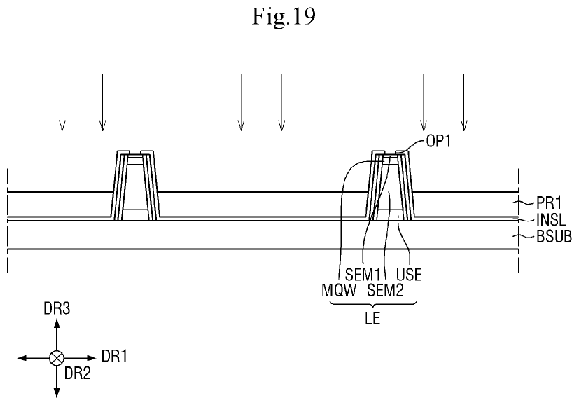

Referring to FIG. 19, the first photoresist PRI is partially exposed to expose portions of the top and side surfaces of the light emitting element. For example, a portion of the first photoresist PR1 may be removed to expose at least the first semiconductor layer SEM1 and the active layer MQW of the light emitting element LE but is not limited thereto.

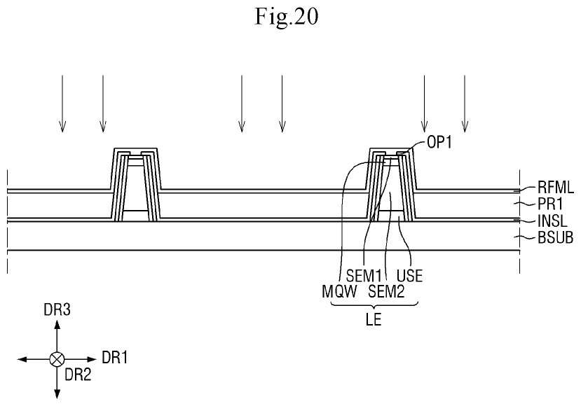

Referring to FIGS. 20 to 22, the contact electrode RFML is formed using the first photoresist PR1 in which a portion of the light emitting element LE is exposed. The contact electrode RFML may be formed similarly to a manufacturing process of the first insulating layer INS1. For example, at least one reflective material layer is stacked on the base substrate BSUB. Thereafter, a second photoresist PR2 may be coated on the light emitting element LE and etched through the etching process to form the contact electrode RFM surrounding the light emitting element LE. Accordingly, the contact electrode RFML surrounding at least the first semiconductor layer SEM1 and the active layer MQW of the light emitting element LE may be formed on the second insulating layer INS2. Also, the contact electrode RFML is in contact with the first semiconductor layer SEM1 through the first opening OP1.

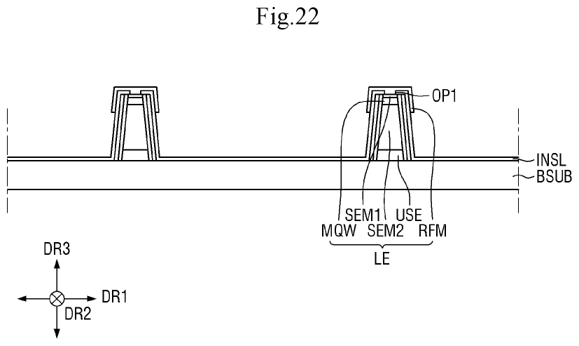

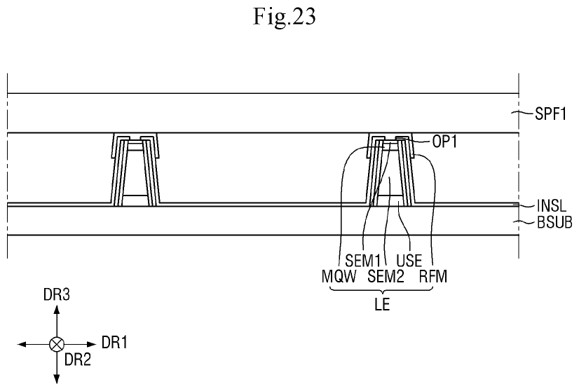

Referring to FIG. 23, a first support film SPF1 is attached to the light emitting elements LE of the base substrate BSUB manufactured in FIG. 22.

For example, the first support film SPF1 is attached to the light emitting elements LE. The first support film SPF1 may be aligned on the light emitting elements LE and attached to each of the contact electrode RFM of the light emitting elements LE. The light emitting elements LE may be arranged in a large number, so that they may be attached to the first support film SPF1 without being detached.

The first support film SPF1 may comprise a support layer and an adhesive layer disposed on the support layer. The support layer may be made of a transparent, mechanically stable material that allows light to penetrate. For example, the support layer may include a transparent polymer such as polyester, polyacrylic, polyepoxy, polyethylene, polystyrene, polyethylene terephthalate, or the like within the spirit and the scope of the disclosure. The adhesive layer may include an adhesive material for bonding the light emitting element LE. For example, the adhesive material may include urethane acrylate, epoxy acrylate, polyester acrylate, and the like within the spirit and the scope of the disclosure. The adhesive material may be a material whose adhesion changes as ultraviolet (UV) light or heat is applied, such that the adhesive layer may be readily separated from the light emitting elements LE.

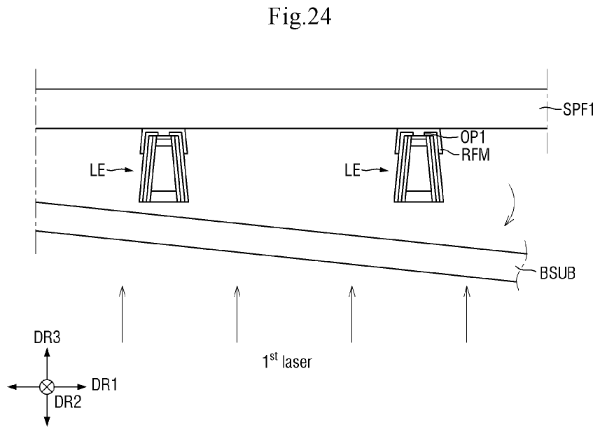

Referring to FIG. 24, the base substrate BSUB is irradiated with a first laser to separate the light emitting elements LE1 and LE3 from the base substrate BSUB. The base substrate BSUB is separated from each third semiconductor layer USE of the light emitting elements LE.

The process for separating the base substrate BSUB may be separated by a laser lift off (LLO) process. The laser lift off process utilizes a laser, and a KrF excimer laser (248 nm wavelength) may be used as the source. The energy density of the excimer laser is irradiated in the range of about 550 550 mJ/cm² to about 950 550 mJ/cm², and the incident area may be in the range of about 50×50 μm² to about 1×1 cm² but is not limited thereto. The base substrate BSUB may be separated from the light emitting elements LE by irradiating the base substrate BSUB with the laser.

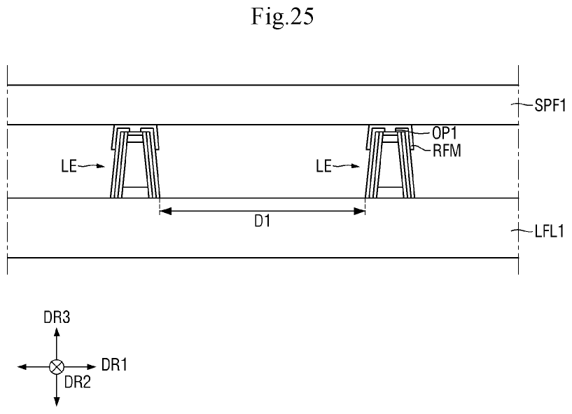

Referring to FIG. 25, a first transfer film LFL1 is attached to the light emitting elements LE separated from the base substrate BSUB.

For example, the first transfer film LFL1 is attached to each of the third semiconductor layers USE of the light emitting elements LE. The first transfer film LFL1 may be aligned on the light emitting elements LE and attached to each third semiconductor layer USE of the light emitting elements LE.

The first transfer film LFL1 may include a stretchable material. The stretchable material may include, for example, polyolefine, polyvinyl chloride (PVC), elastomeric silicone, elastomeric polyurethane, elastomeric polyisoprene, and the like within the spirit and the scope of the disclosure. The first transfer film LFL1 may also include the support layer and the adhesive layer, such as the first support film SPF1 described above, to bond and support the light emitting elements LE.

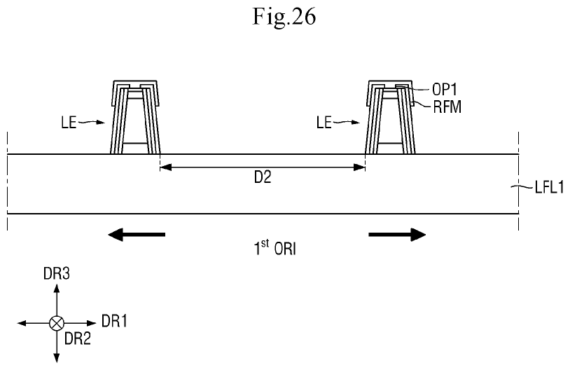

Referring to FIG. 26, the first support film SPF1 is separated from the light emitting elements LE, and the first transfer film LFL1 is stretched (1^{st} ORI). After applying ultraviolet light or heat to the first support film SPF1 to reduce the adhesive strength of the adhesive layer of the first support film SPF1, the first support film SPF1 may be physically or naturally separated. The light emitting elements LE may be disposed in a dot shape on the first transfer film LFL1 while being spaced apart from each other by a selectable first distance D1.

The first transfer film LFL1 may be stretched two-dimensionally in the first and second directions DR1 and DR2. As the first transfer film LFL1 is stretched, the distance between the light emitting elements LE attached to the first transfer film LFL1 may be a second distance D2 greater than the first distance D1 of FIG. 25. Stretching strength (or tensile strength) of the first transfer film LFL1 may be adjusted according to a desired spacing between the light emitting elements LE, and may be, for example, about 120 gf/inch. However, it is not limited thereto.

In this embodiment, it has been described that one stretching process was performed as an example but is not limited thereto. The stretching process may be performed multiple times.

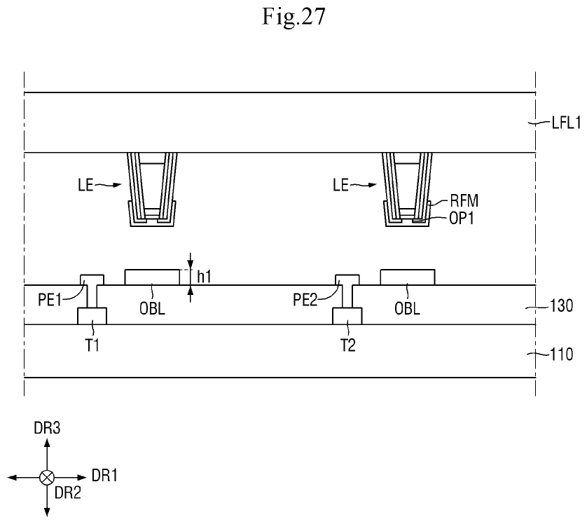

Referring to FIG. 27, the first transfer film LFL1 is bonded on the substrate 110 and the light emitting elements LE are electrically connected to the first and second pixel electrodes PE1 and PE2 through the connection electrode 150.

The first transfer film LFL1 is aligned on the substrate 110. At this time, the contact electrode RFM of the light emitting element LE formed on the first transfer film LFL1 is aligned to face the substrate 110. As shown in FIG. 6, the substrate 110 may have the pixel electrodes PEL and PE2 and the organic pattern layer OBL formed thereon. Align the contact electrode RFM of the light emitting element LE to be disposed on the organic pattern layer OBL. A height h1 of the organic pattern layer OBL may be about 2 μm but is not limited thereto.

The substrate 110 and the first transfer film LFL1 are bonded. For example, the contact electrode RFM of the light emitting element LE formed on the first transfer film LFL1 is aligned on the organic pattern layer OBL of the substrate 110. At this time, the contact electrode RFM of the light emitting element LE is in contact with the organic pattern layer OBL. Subsequently, heat and pressure are applied to the organic pattern layer OBL to cure the organic pattern layer OBL. As a result, the light emitting element LE and the organic pattern layer OBL are primarily bonded. The heat and pressure at this time are lower than those of a eutectic bonding process. For example, the eutectic bonding process is a relatively high-temperature process of about 200 to 400 degrees, whereas the organic material curing process is a relatively low-temperature process of 80 to 200 degrees. Therefore, the light emitting element LE may be bonded to the organic pattern layer OBL at a relatively lower temperature and pressure compared to the eutectic bonding process.

The eutectic bonding process required different thermal and pressure conditions depending on the length and diameter of the light emitting element. Also, it is difficult to realize the state of the bonding metal evenly in the eutectic bonding process, and the uneven state of the bonding metal is likely to be expressed as a luminance scatter. In one embodiment, since bonding is performed using the organic pattern layer OBL, problems caused by eutectic bonding may be solved by omitting eutectic bonding.

The first transfer film LFL1 is removed. The first transfer film LFL1 is separated from the light emitting elements LE. After reducing the adhesive strength of the adhesive layer of the first transfer film LFL1 by applying ultraviolet light or heat to the first transfer film LFL1, the first transfer film LFL1 may be physically or naturally separated.

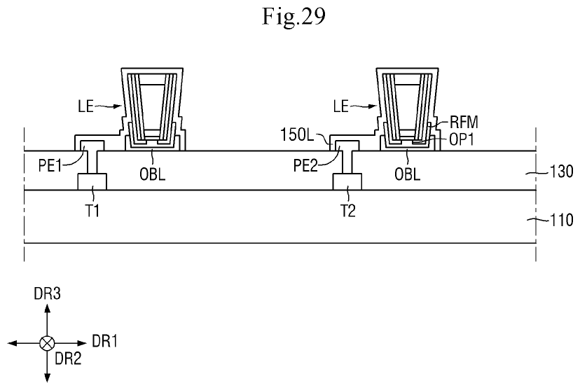

Referring to FIGS. 29 to 31, the connection electrode 150 and the first via layer VIA1 electrically connecting the pixel electrode PE1 and the light emitting element LE are formed.

The connecting electrode 150 may be formed by stacking an electrode material layer 150L to cover both the pixel electrodes PEL and PE2 and the light emitting element LE, and etching it through the etching process with the first via layer VIA1 as a mask to form the connecting electrode 150.

For example, referring to FIG. 29, the electrode material layer 150L is laminated to cover both the pixel electrodes PEL and PE2 and the light emitting element LE. The electrode material layer 150L may be stacked along the top and side surfaces of the pixel electrodes PE1 and PE2 and extend along the top and side surfaces of the light emitting element LE. The electrode material layers 150L corresponding to different light emitting areas are spaced apart from each other.

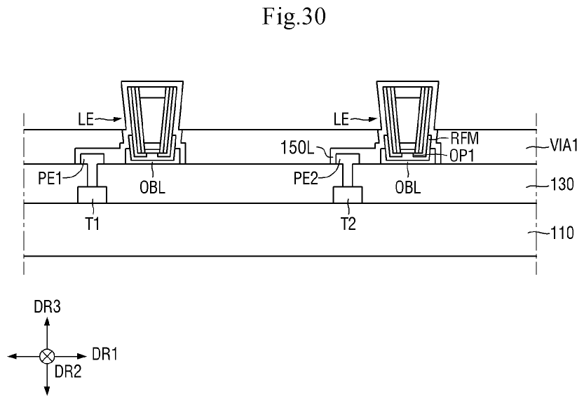

Referring to FIG. 30, the first via layer VIA1 is formed on the substrate 110 on which the light emitting elements LE surrounded by the electrode material layer 150L are formed.

The first via layer VIA1 may be formed on the electrode material layer 150L. The first via layer VIA1 is formed on the electrode material layer 150L. The first via layer VIA1 may be formed at a height higher than the height of the active layer MQW of the light emitting element LE.

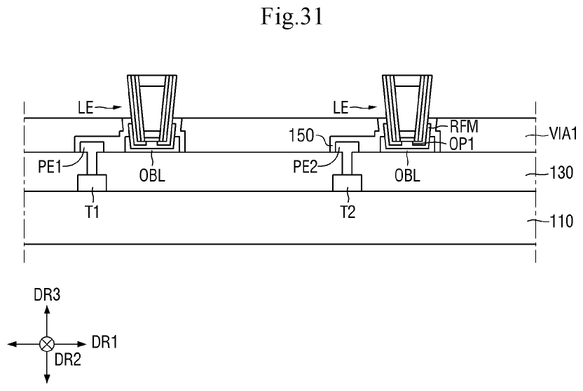

Referring to FIG. 31, the electrode material layer 150L is etched to form the connection electrode 150. The electrode material layer 150L may be etched using the first via layer VIA1 as a mask. Accordingly, the height of the upper surface of the first via layer VIA1 is equal to one end of the connection electrode 150 disposed along the side of the light emitting element LE. The electrode material layer 150L may be etched using, for example, a wet etching process, but is not limited thereto.

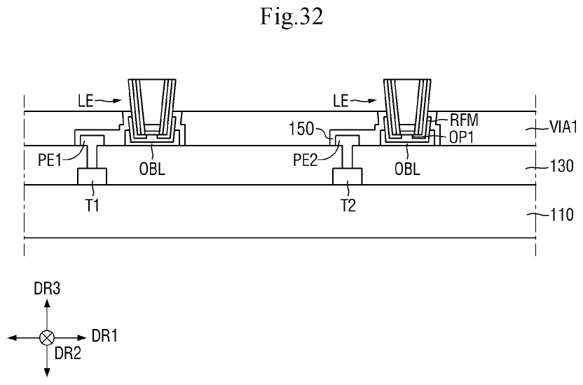

Subsequently, referring to FIG. 32, portions of the first insulating layer INS1, the reflective layer RFL, and the second insulating layer INS2 of the light emitting element LE and the third semiconductor layer USE are etched and removed.

For example, the first insulating layer INS1, the reflective layer RFL, and the second insulating layer INS2 surrounding the light emitting element LE are removed using a dry etching process. Only portions of the first insulating layer INS1, the reflective layer RFL, and the second insulating layer INS2 surrounding the third semiconductor layer USE are removed to expose the third semiconductor layer USE. In case that the third semiconductor layer USE is exposed, the third semiconductor layer USE is removed using the dry etching process. Since the third semiconductor layer USE does not exhibit conductivity, it is removed for connection of the common electrode CE. At this time, the first via layer (VIA1) may be partially etched by the dry etching process described above and formed to be disposed inwardly from the sides of the first insulating layer INS1, the reflective layer RFL, and the second insulating layer INS2.

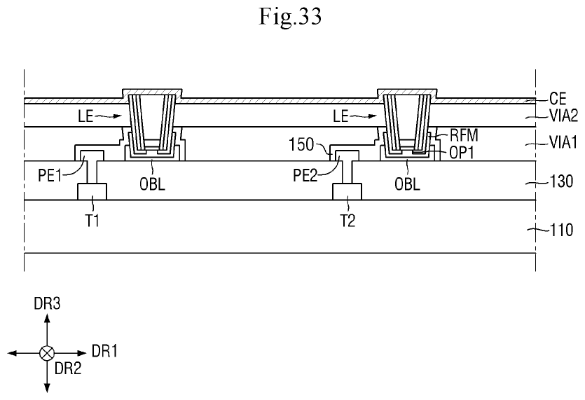

Referring to FIG. 33, the second via layer VIA2 and the common electrode CE are formed on the first via layer VIA1.

For example, the second via layer VIA2 may be formed on the first via layer VIA1. The second via layer VIA2 may be manufactured in the same manner as the above-described first via layer VIA1. The second via layer VIA2 may be formed to a height lower than that of the second semiconductor layer SEM2 of the light emitting element LE.

The common electrode CE may be formed on the light emitting element LE and the second via layer VIA2. The common electrode CE is continuously formed over the entire display area. The common electrode CE covers the second via layer VIA2 and the light emitting element LE, and directly contacts them. The common electrode CE is formed in direct contact with the upper surface of the second semiconductor layer SEM2 of the light emitting element LE.

As shown in FIG. 6, the display device 10 according to one embodiment is manufactured by forming a partition wall part, a wavelength control layer, a color filter layer, and the like within the spirit and the scope of the disclosure.

However, the aspects of the disclosure are not restricted to the ones set forth herein. The above and other aspects of the disclosure will become more apparent to one of ordinary skill in the art to which the disclosure pertains by referencing the claims, with equivalents thereof to be included therein.

What is claimed is:

1. A display device comprising:
an electrode disposed on a substrate;
an organic pattern layer disposed on the substrate and spaced apart from the electrode;
a light emitting element disposed on the organic pattern layer, the light emitting element including a contact electrode contacting the organic pattern layer, a first semiconductor layer, an active layer, and a second semiconductor layer sequentially disposed on the contact electrode; and
a connection electrode electrically connecting the electrode to the contact electrode,
wherein the connection electrode is disposed along an upper surface of the electrode, a side surface of the organic pattern layer, and a side surface of the contact electrode.

2. The display device of claim 1, wherein
the display device includes a light emitting area and a non-emitting area, and
the organic pattern layer overlaps the emitting area and does not overlap the non-emitting area.

3. The display device of claim 2, wherein the organic pattern layer has a substantially island pattern shape.

4. The display device of claim 2, wherein the contact electrode comprises:
a first portion disposed on the first semiconductor layer and contacting the first semiconductor layer,
a second portion extending from the first portion and surrounding at least a portion of a side surface of the light emitting element.

5. The display device of claim 4, wherein the connection electrode surrounds at least a portion of a side surface of the light emitting element on the contact electrode.

6. The display device of claim 4, further comprising:
a first via layer disposed on the connection electrode and the substrate on which the connection electrode is not disposed;
a second via layer disposed on the first via layer; and
a common electrode disposed on the light emitting element.

7. The display device of claim 6, wherein an upper surface of the first via layer has a same height as an end of a connection electrode disposed along the second portion of the contact electrode.

8. The display device of claim 2, wherein the electrode overlaps the non-emitting area and does not overlap the emitting area.

9. The display device of claim 4, wherein
the light emitting element further comprises a first insulating layer surrounding side surfaces of the first semiconductor layer, the active layer, the second semiconductor layer and an upper surface of the first semiconductor layer, the first insulating layer having a first opening on the first semiconductor layer, and
the contact electrode directly contacts the first semiconductor layer through the first opening the first insulating layer.

10. The display device of claim 9, wherein
the light emitting element further comprises:
a second insulating layer surrounding side surfaces of the first semiconductor layer, the active layer, and the second semiconductor layer and an upper surface of the first semiconductor layer; and
a reflective layer surrounding side surfaces of the light emitting element on the second insulating layer, and
the first insulating layer is disposed on the reflective layer and directly contacts the second portion of the contact electrode.

11. The display device of claim 10, wherein the reflective layer is surrounded by the first insulating layer and the second insulating layer and does not contact the contact electrode.

12. The display device of claim 6, further comprising:
a partition wall part disposed on the common electrode and overlapping the non-emitting area;
a wavelength conversion layer disposed between the partition wall part; and
a color filter layer disposed on the wavelength conversion layer.

13. A display device comprising:
an electrode disposed on a substrate;
an organic pattern layer disposed on the electrode;
a light emitting element disposed on the organic pattern layer, the light emitting element including a contact electrode contacting the organic pattern layer, a first semiconductor layer, an active layer, and a second semiconductor layer sequentially disposed on the contact electrode; and
a connection electrode electrically connecting the electrode to the contact electrode, wherein
a portion of an upper surface of the electrode does not overlap the organic pattern layer, and
the connection electrode is disposed on a portion of an upper surface of the electrode that does not overlap the organic pattern layer, a side surface of the organic pattern layer, and a side surface of the contact electrode.

14. The display device of claim 13, wherein the contact electrode comprises:
a first portion disposed on the first semiconductor layer and contacting the first semiconductor layer,
a second portion extending from the first portion and surrounding at least a portion of a side surface of the light emitting element.

15. The display device of claim 14, wherein the connection electrode surrounds at least a portion of a side surface of the light emitting element on the contact electrode.

16. The display device of claim 14, further comprising:
a first via layer disposed on the connection electrode and the substrate on which the connection electrode is not disposed;
a second via layer disposed on the first via layer; and
a common electrode disposed on the light emitting element.

17. The display device of claim 16, wherein an upper surface of the first via layer has a same height as an end of a connection electrode disposed along the second portion of the contact electrode.

18. The display device of claim 15, wherein
the light emitting element further comprises a first insulating layer surrounding side surfaces of the first semiconductor layer, the active layer, the second semiconductor layer and an upper surface of the first semiconductor layer, the first insulating layer having a first opening on the first semiconductor layer, and
the contact electrode directly contacts the first semiconductor layer through the first opening of the first insulating layer.

19. The display device of claim 18, wherein
the light emitting element further comprises:
a second insulating layer surrounding side surfaces of the first semiconductor layer, the active layer, and the second semiconductor layer and an upper surface of the first semiconductor layer; and
a reflective layer surrounding side surfaces of the light emitting element on the second insulating layer, and
the first insulating layer is disposed on the reflective layer and directly contacts the second portion of the contact electrode.

20. The display device of claim 16, wherein
the display device includes an emitting area and a non-emitting area, and
the display device further comprises:
a partition wall part disposed on the common electrode and overlapping the non-emitting area;
a wavelength conversion layer disposed between the partition wall part; and
a color filter layer disposed on the wavelength conversion layer.
